(19) United States
(12) Patent Application Publication
(10) Pub. No.: US 2024/0006499 A1
(43) Pub. Date: Jan. 4, 2024

(54) GATE SPACER IN STACKED GATE-ALL-AROUND (GAA) DEVICE ARCHITECTURE

(71) Applicant: Intel Corporation, Santa Clara, CA (US)

(72) Inventors: Cheng-Ying Huang, Hillsboro, OR (US); Kai Loon Cheong, Beaverton, OR (US); Pooja Nath, Hillsboro, OR (US); Susmita Ghose, Hillsboro, OR (US); Rambert Nahm, Beaverton, OR (US); Natalie Briggs, Hillsboro, OR (US); Charles C. Kuo, Hillsboro, OR (US); Nicole K. Thomas, Portland, OR (US); Munzarin F. Qayyum, Hillsboro, OR (US); Marko Radosavljevic, Portland, OR (US); Jack T. Kavalieros, Portland, OR (US); Thoe Michaelos, Portland, OR (US); David Kohen, Hillsboro, OR (US)

(73) Assignee: Intel Corporation, Santa Clara, CA (US)

(21) Appl. No.: 17/854,242

(22) Filed: Jun. 30, 2022

(51) Int. Cl. H01L 29/423; H01L 29/786; H01L 29/66

(52) U.S. Cl. CPC H01L 29/42392; H01L 29/78696; H01L 29/6681

(57) ABSTRACT

An integrated circuit includes an upper semiconductor body extending in a first direction from an upper source region to an upper drain region, and a lower semiconductor body extending in the first direction from a lower source region to a lower drain region. The upper body is spaced vertically from the lower body in a second direction orthogonal to the first direction. A gate spacer structure is adjacent to the upper and lower source regions. In an example, the gate spacer structure includes (i) a first section having a first dimension in the first direction, and (ii) a second section having a second dimension in the first direction. In an example, the first dimension is different from the second dimension by at least 1 nm. In some cases, an intermediate portion of the gate spacer structure extends laterally within a given gate structure, or between upper and lower gate structures.

### FIELD OF THE DISCLOSURE

The present disclosure relates to integrated circuits, and more particularly, to gate spacers in stacked transistor device architectures.

### BACKGROUND

Integrated circuitry continues to scale to smaller feature dimensions and higher transistor densities. A more recent development with respect to increasing transistor density is generally referred to as three-dimensional (3D) integration, which expands transistor density by exploiting the z-dimension (build upwards rather than laterally outwards in the x- and y-dimensions). For example, multiple transistors are stacked in a vertical direction.

### BRIEF DESCRIPTION OF THE DRAWINGS

FIG. 1A is a cross-sectional view of a portion of an integrated circuit structure that includes a lower device, and an upper device stacked vertically over the lower device, where a section of a gate spacer structure of the integrated circuit structure has (i) a first section having a first dimension in a lateral direction, and (ii) a second section having a second dimension in the lateral direction, wherein the first dimension is different from the second dimension by at least 1 nm, according to an embodiment of the present disclosure.

FIG. 1B is a cross-sectional view of a portion of an integrated circuit structure that is at least in part similar to the integrated circuit structure of FIG. 1A, wherein the gate spacer structures in FIG. 1B have a different profile compared to that in FIG. 1A, according to an embodiment of the present disclosure.

FIG. 1C is a cross-sectional view of a portion of an integrated circuit structure that is at least in part similar to the integrated circuit structure of FIG. 1A, wherein in FIG. 1C an isolation structure separates an upper gate electrode of the upper device from a lower gate electrode of the lower device, according to an embodiment of the present disclosure.

FIG. 2A is a cross-sectional view of a portion of an integrated circuit structure that includes a lower device, an upper device stacked vertically over the lower device, a first gate spacer structure and a second gate spacer structure, and one or more dummy nanoribbons comprising dielectric material extending from a source isolation region to a drain isolation region and between the first gate spacer structure and the second gate spacer structure, according to an embodiment of the present disclosure.

FIG. 2B is a cross-sectional view of a portion of an integrated circuit structure that is at least similar to the integrated circuit structure of FIG. 2A, and wherein in FIG. 2B at least a part of a dummy nanoribbon structure comprising dielectric material extends laterally between an upper (or lower) source region and an upper (or lower) drain region, according to an embodiment of the present disclosure.

FIG. 3 is a cross-sectional view of a portion of an integrated circuit structure that includes a lower device, an upper device stacked vertically above the lower device, a first gate spacer structure and a second gate spacer structure, one or more dummy nanoribbons comprising dielectric material laterally extending between the first gate spacer structure and the second gate spacer structure, and partial nanoribbons comprising semiconductor material above and/or below individual ones of the dummy nanoribbons, according to an embodiment of the present disclosure.

FIG. 4A is a cross-sectional view of a portion of an integrated circuit structure that includes a lower device, an upper device stacked vertically over the lower device, and a continuous and monolithic gate spacer structure that comprises (i) a first vertical section adjacent to the source regions of the upper and lower devices, (ii) a second vertical section adjacent to the drain regions of the upper and lower devices, and (iii) a horizontal section extending laterally from the first vertical section to the second vertical section, according to an embodiment of the present disclosure.

FIG. 4B is a cross-sectional view of a portion of an integrated circuit structure that includes a lower device, an upper device stacked vertically over the lower device, and a continuous and monolithic gate spacer structure that comprises (i) a first vertical section adjacent to the source regions of the upper and lower devices, (ii) a second vertical section adjacent to the drain regions of the upper and lower devices, and (iii) a horizontal section extending laterally from the first vertical section to the second vertical section, wherein the integrated circuit structure further comprises partial nanoribbons on an upper surface and/or lower surface of the horizontal section of the gate spacer structure, according to an embodiment of the present disclosure.

FIG. 5 illustrates a flowchart depicting a method of forming any of the example integrated circuit structures of FIG. 1A-C or 2A-B, in accordance with an embodiment of the present disclosure.

FIGS. 6A, 6B, 6C, 6D, 6D1, 6E, 6E1, 6F, 6F1, 6G, 6G1, 6H, 6H1, 6I, 6I1, 6J, 6J1, 6K, and 6K1 collectively illustrate cross-sectional views of an example integrated circuit device semiconductor structure (e.g., the integrated circuit structures of FIG. 1A-C or 2A-B) in various stages of processing, in accordance with an embodiment of the present disclosure.

FIG. 7 illustrates a flowchart depicting a method of forming any of the example integrated circuit structure of FIG. 3, in accordance with an embodiment of the present disclosure.

FIGS. 8A, 8B, 8C, 8D, 8E, and 8F collectively illustrate cross-sectional views of an example integrated circuit device semiconductor structure (e.g., the integrated circuit structure of FIG. 3) in various stages of processing, in accordance with an embodiment of the present disclosure.

FIG. 9 illustrates a flowchart depicting a method of forming any of the example integrated circuit structure 400 of FIGS. 4A-B, in accordance with an embodiment of the present disclosure.

FIGS. 10A, 10B, 10C, 10D, 10E, and 10F collectively illustrate cross-sectional views of an example integrated circuit device semiconductor structure (e.g., the integrated circuit structure of FIG. 4A-B) in various stages of processing, in accordance with an embodiment of the present disclosure.

FIG. 11 illustrates a computing system implemented with integrated circuit structures formed using the techniques disclosed herein, in accordance with some embodiments of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Gate spacer forming techniques are described herein. In an embodiment, an integrated circuit structure is disclosed that includes vertically stacked upper and lower gate-all-around (GAA) semiconductor devices having an internal gate spacer between a corresponding gate structure and a corresponding source or drain region, wherein such an internal gate spacer has a vertical section for separating a gate structure from a corresponding source or drain region, and a horizontal section that extends laterally from the vertical section. In one such embodiment, the channel region is a nanoribbon, a nanosheet, or a nanowire, although other example bodies of semiconductor material may also be used. The upper device comprises an upper semiconductor body extending in a first direction from an upper source region to an upper drain region of the upper device. The lower device comprises a lower semiconductor body extending in the first direction from a lower source region to a lower drain region of the lower device. The upper semiconductor body is spaced vertically from the lower semiconductor body in a second direction orthogonal to the first direction. A first gate spacer structure is adjacent to the upper source region and the lower source region. In an example, the first gate spacer structure comprises (i) a first section having a first dimension in the first direction, and (ii) a second section having a second dimension in the first direction, wherein the first dimension is different from the second dimension by at least 1 nanometer (nm). A second gate spacer structure is adjacent to the upper drain region and the lower drain region. In an example, the second gate spacer structure comprises (i) a third section having the first dimension in the first direction, and (ii) a fourth section having the second dimension in the first direction.

In another embodiment, an integrated circuit structure comprises an upper device above a lower device, e.g., to form a vertical stack of devices. The upper device comprises an upper source region, an upper drain region, an upper body of semiconductor material laterally extending from the upper source region to the upper drain region, and an upper gate structure wrapping around at least a corresponding section of the upper body. The lower device comprises a lower source region, a lower drain region, a lower body of semiconductor material laterally extending from the lower source region to the lower drain region, and a lower gate structure wrapping around at least a corresponding section of the lower body. In an example, a gate spacer structure includes (i) an upper portion separating the upper gate structure from the upper source region, (ii) a lower portion separating the lower gate structure from the lower source region, and (iii) an intermediate portion between the upper and lower portions. In one such example, the intermediate portion extends laterally within at least one of the upper and lower gate structures, or extends fully between the upper and lower gate structures.

In yet another embodiment, an integrated circuit structure comprises an upper source region, a lower source region below the upper source region, and an isolation region between the upper source region and the lower source region. A spacer structure comprises dielectric material and has (i) an outer sidewall adjacent to the upper source region, the lower source region, and the isolation region, and (ii) an inner sidewall opposite the outer sidewall. In one such example, an entirety of the outer sidewall is substantially planar in profile, and the inner sidewall has (i) a first section and (ii) a second section that is laterally offset from the first section by at least 1 nm, so as to be non-planar in profile (e.g., corrugated or otherwise non-linear). Numerous variations and embodiments will be apparent in light of this disclosure.

General Overview

A stacked device architecture can in include an upper device stacked above a lower device. In some cases, the upper and lower devices can be arranged in a complementary metal oxide semiconductor (CMOS) architecture. For instance, the upper device can be one of an n-channel metal-oxide semiconductor (NMOS) device or a p-channel metal-oxide semiconductor (PMOS) device, and the lower device can be the other of the NMOS or the PMOS device.

Techniques are provided herein to form gate spacer structures for such stacked device architecture. For example, in an example, each of the upper and lower devices may be a gate all around (GAA) transistor having any number of nanoribbons extending laterally from a corresponding source region to a corresponding drain region. As will be appreciated in light of this disclosure, reference to nanoribbons as channel regions is also intended to include other gate-all-around or multi-gate channel regions, such as nanowires, nanosheets, and other such semiconductor bodies around which a gate structure can at least partially wrap (such as the semiconductor bodies of a forksheet device or a fin-based device). In an example, assume that vertical spacing between adjacent ones of the upper nanoribbons is d1, where adjacent ones of the lower nanoribbons are also at the vertical spacing of about d1. Also assume that the lowermost one of the upper nanoribbons of the upper device and the uppermost one of the lower nanoribbons of the lower device is at a distance of d2. Thus, d2 is the vertical separation between the upper nanoribbons of the upper device and the lower nanoribbons of the lower device. The distance d2 is substantially greater than d1. For example, d1 can be in the range of 2-12 nm or in any sub-range therebetween, and d2 can be in the range of 8-80 nm or in any sub-range therebetween. To form the stacked device architecture, a fin comprising alternating layers of sacrificial material and channel material is formed, and end portions of the sacrificial material are removed to form a recess. Subsequently, this recess is filled with dielectric material, to form internal gate spacers. Note that the distances d1 and d2 are substantially different, thereby causing uneven distances between various nanoribbons (e.g., distance d1 between adjacent nanoribbons of each device is much smaller than distance d2 between nanoribbons of the two devices). The uneven spacing causes fabrication challenges when forming internal spacer structures that can lead to parasitic capacitance and shorting between the gate electrode and source or drain regions of a given semiconductor device. For example, a section of the above discussed recess between the nanoribbons of the two devices (within distance d2) may not be completely filled with the dielectric material of the gate spacers, leading to the above-described problems.

So, to facilitate formation of the gate spacer structures in example of the present description, the overall gate spacer structure can be formed in sections using separate etching and deposition processes. For example, in one embodiment, a gate spacer structure comprising vertical and horizontal sections is formed, using more than one type of sacrificial material. For example, in the fin structure used to form the nanoribbons of the upper and lower devices, a first sacrificial material layer and a second sacrificial material layer are interleaved with the channel material layers. In an example, the first sacrificial material is etch selective with respect to the second sacrificial material, such that an etch process to etch the first sacrificial material does not substantially etch the second sacrificial material, and/or vice-versa. The etch selectivity can be achieved by making the first and second sacrificial materials compositionally and/or elementally different. For example, each of the first sacrificial material and the second sacrificial material may comprise silicon germanium (SiGe), but with a different germanium content within the first and second sacrificial materials, thereby resulting in the etch selectivity between the first and second sacrificial materials. In another example, the first and second sacrificial materials may be doped differently, thereby resulting in the etch selectivity between the first and second sacrificial materials.

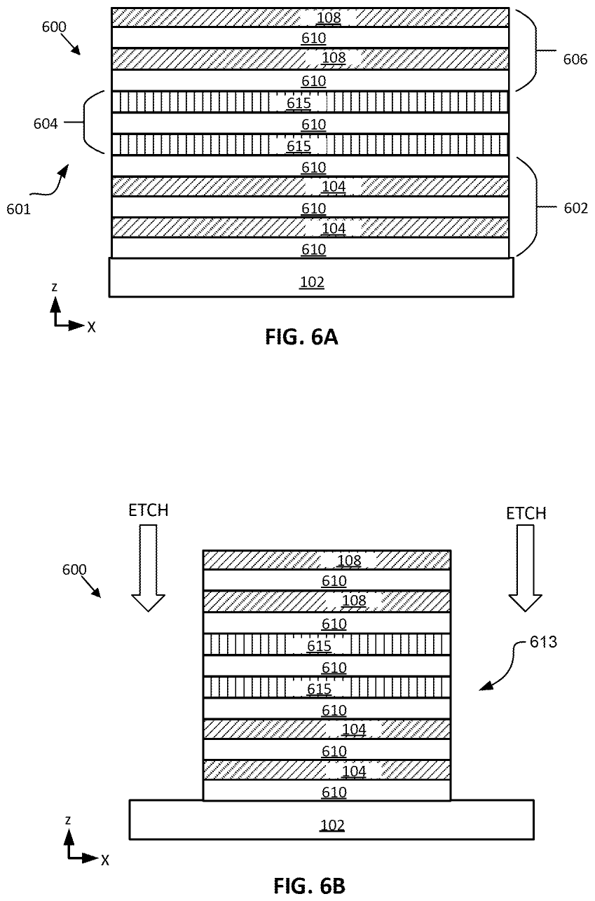

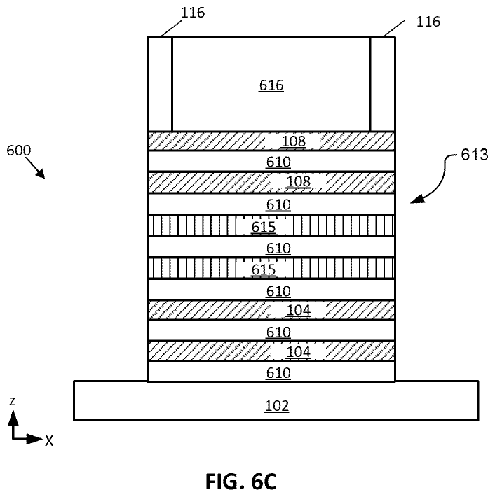

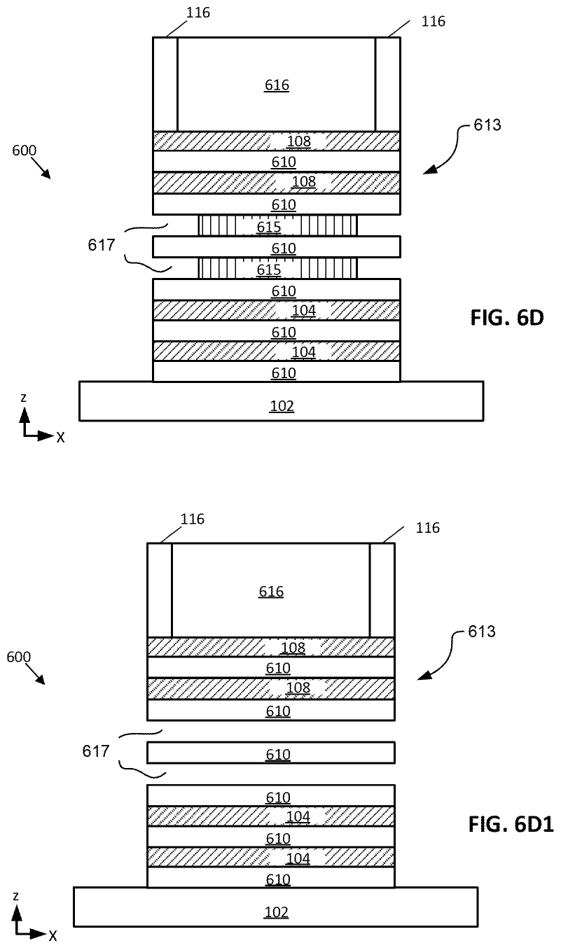

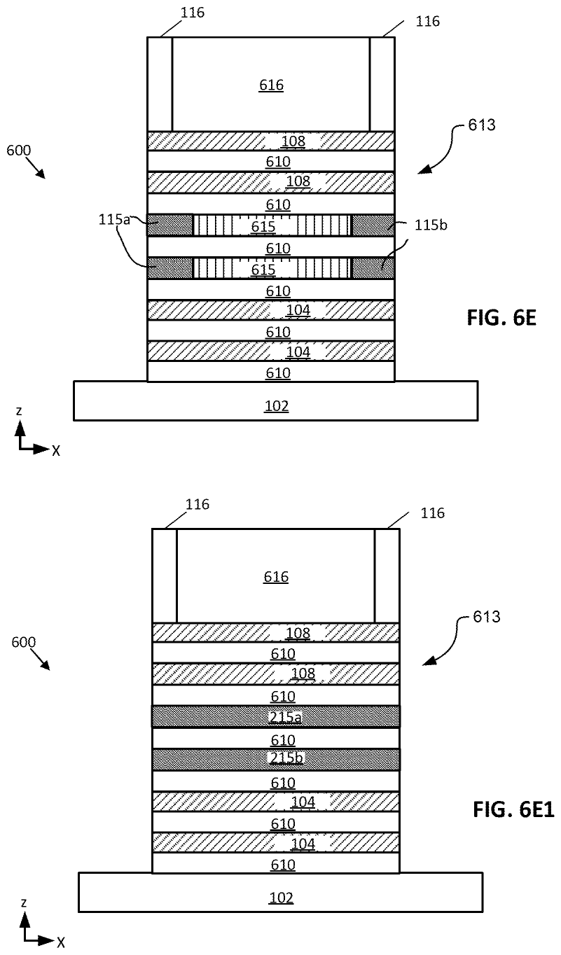

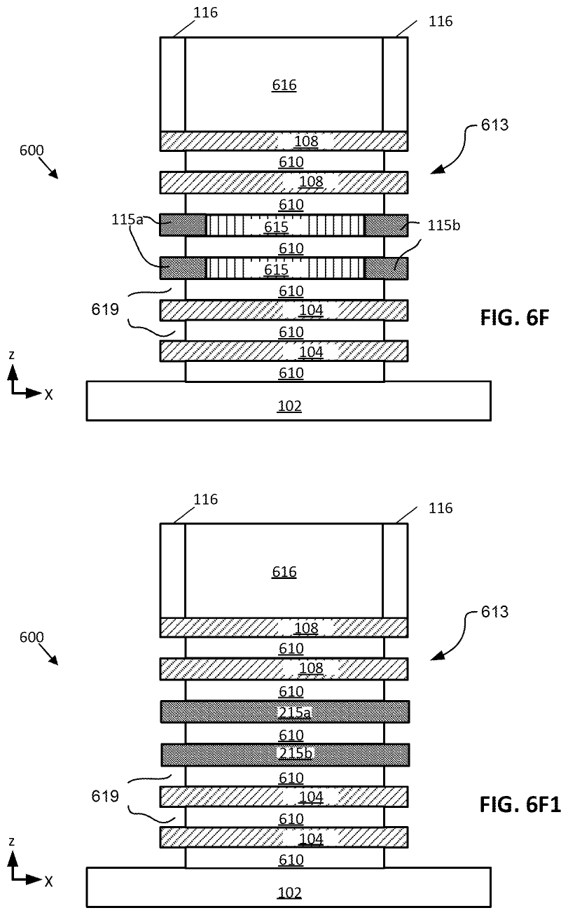

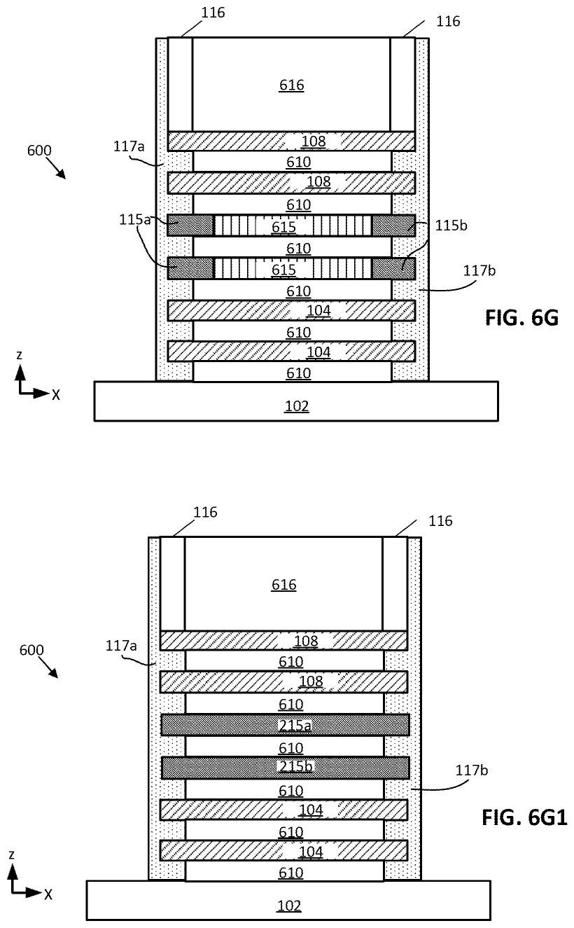

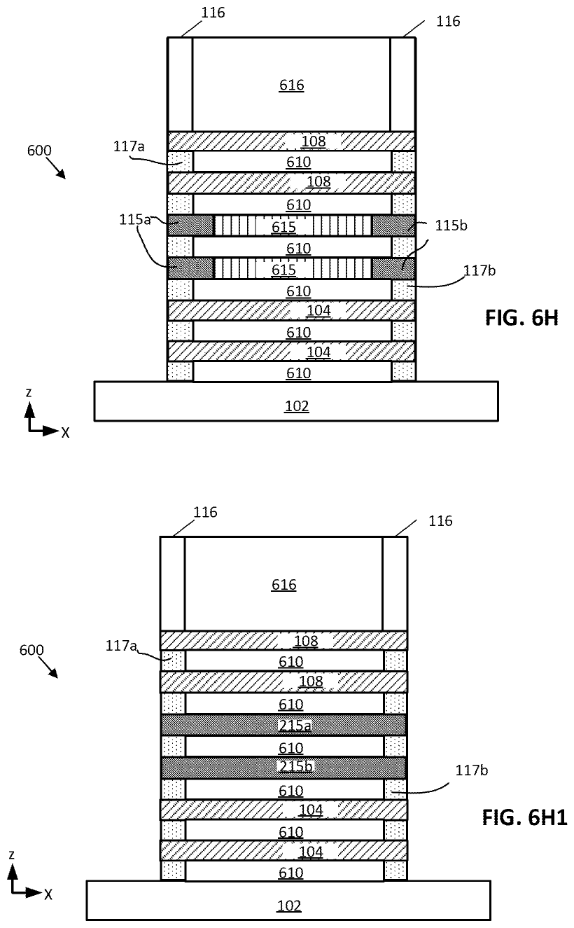

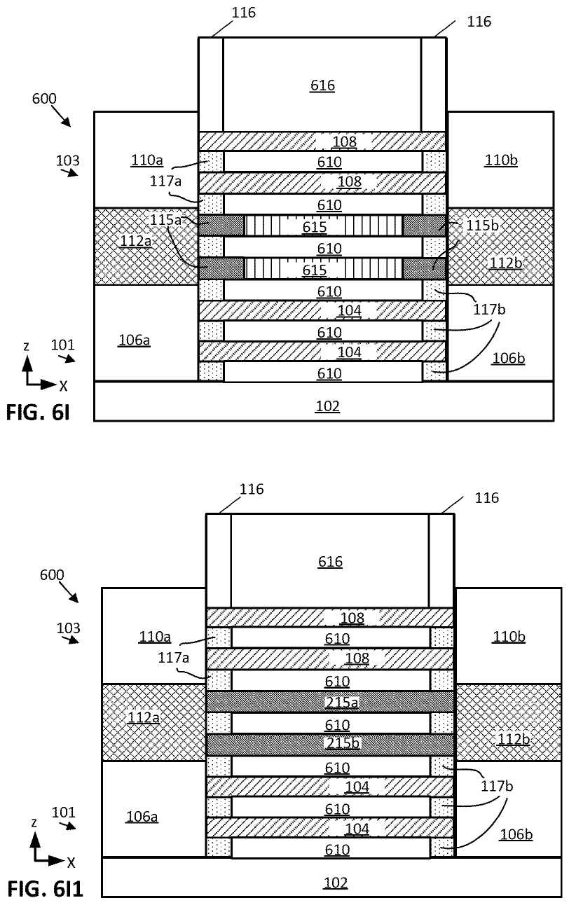

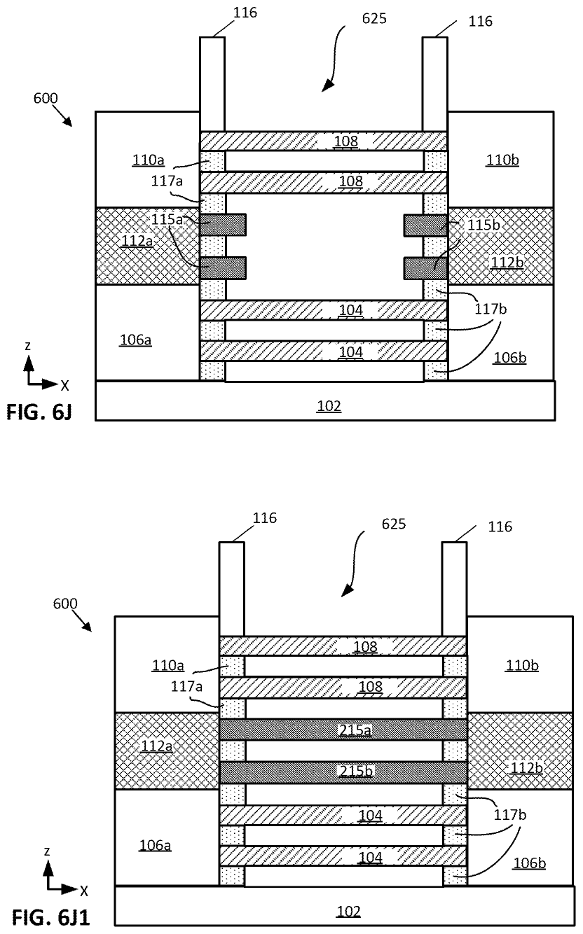

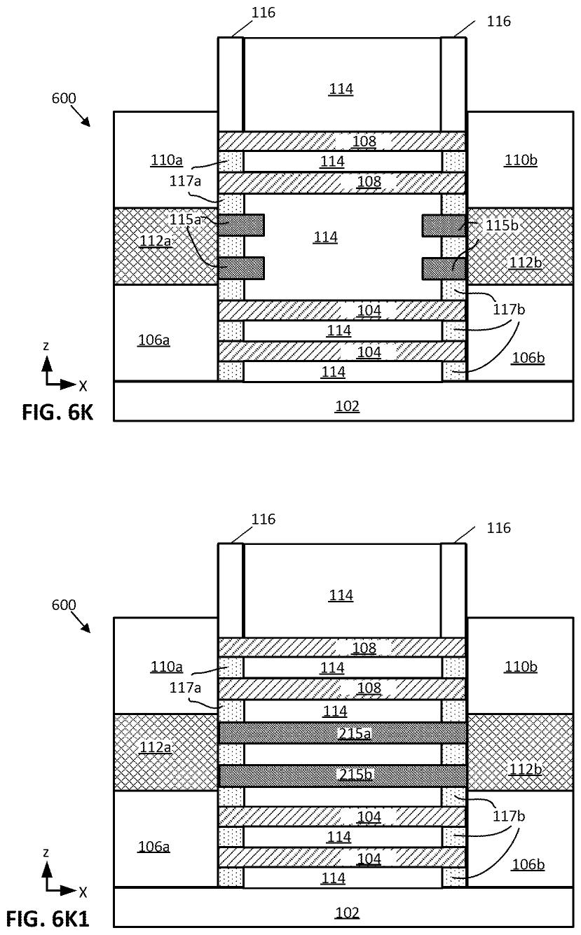

For example, assume a fin comprising (i) a lower portion that includes alternating layers of channel material for lower nanoribbons and the first sacrificial material, (ii) an intermediate portion that includes alternating layers of the second sacrificial material and the first sacrificial material, and (iii) an upper portion that includes alternating layers of channel material for the upper nanoribbons and the first sacrificial material. In one example case, the second sacrificial material of the fin is recessed, where in a first such example only end portions of the second sacrificial material are recessed (e.g., see FIG. 6D), or in a second such example an entirety of the second sacrificial material is recessed or otherwise substantially removed (e.g., see FIG. 6D1). The etch process to etch the second sacrificial material does not substantially recess the first sacrificial material or the channel materials, given the selective nature of the recess etch. The recess formed by the second sacrificial material is then filled with dielectric material, to form the horizontal sections of the gate spacers (e.g., see FIGS. 6E and 6E1). Note that the second sacrificial material is layered between the upper and lower nanoribbons. Subsequently, end portions of the first sacrificial material are recessed (e.g., see FIGS. 6F and 6F 1), and the vertical sections of the gate spacers are formed (e.g., see FIGS. 6H and 6H1). Thus, a given gate spacer is formed in two different etch and deposition processes: the formation of the horizontal section within the above discussed distance d2, and the formation of the vertical sections within the above discussed distance d1. Note that the vertical sections can be formed before the horizontal sections, or vice-versa, given the etch selectivities. In any such cases, the difference between the distances d1 and d2 does not affect the gate spacer formation process, and the thus formed gate spacer has a substantially planar or linear outer sidewall. Subsequently, the source and drain regions can be epitaxially formed adjacent corresponding outer sidewalls, followed by gate processing that includes removal of the sacrificial gate materials and releasing the nanoribbons, and formation of the final gate stack.

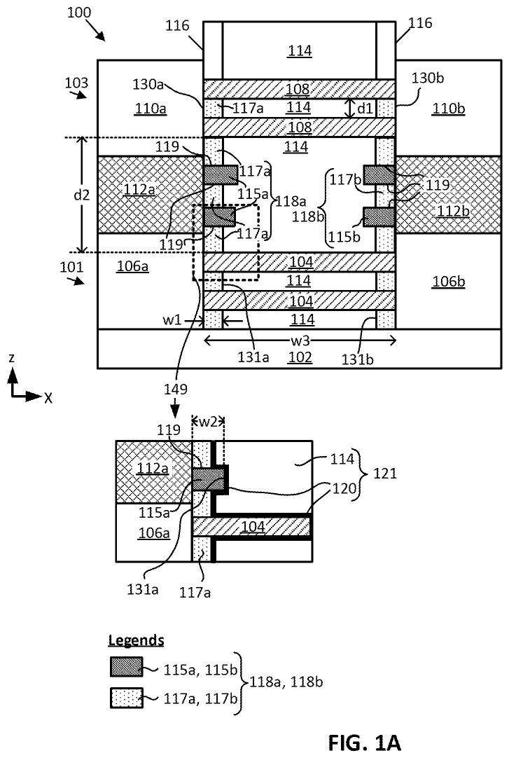

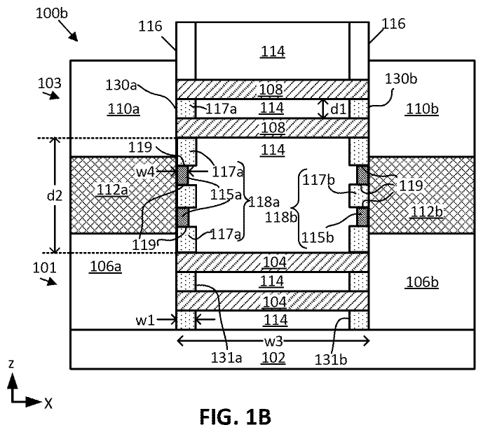

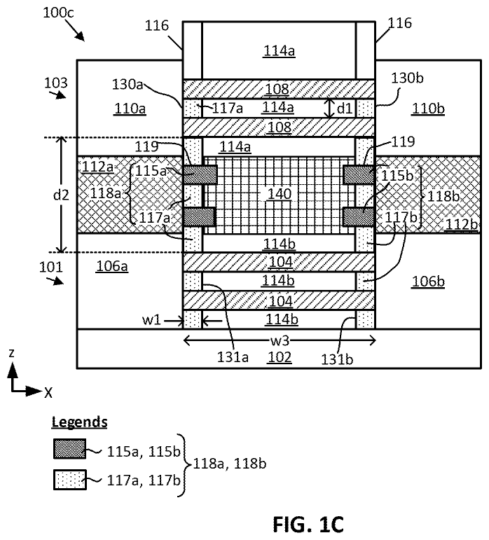

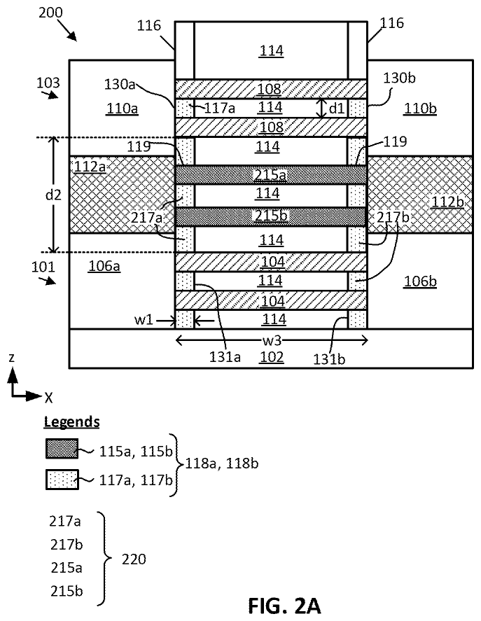

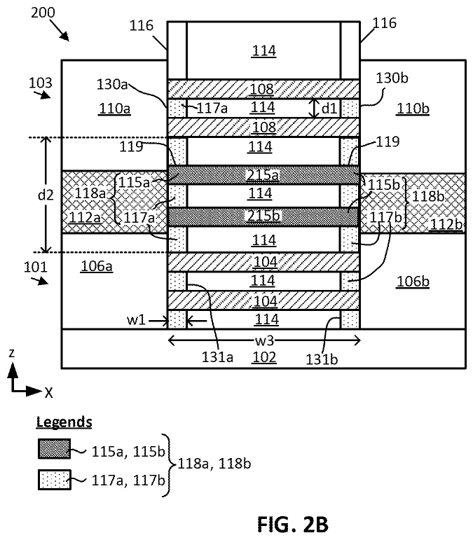

In some examples of the resultant stacked device structure, a first vertical section of a first spacer is adjacent to (i) each of the upper and lower source regions of the upper and lower devices, respectively, and (ii) a first isolation region between the upper and lower source regions. Similarly, a second vertical section of a second spacer is adjacent to each of (i) the upper and lower drain regions of the upper and lower devices, respectively, and (ii) a second isolation region between the upper and lower drain regions. A first horizontal section of the first spacer extends laterally from the first vertical section towards the second vertical section of the second spacer, and a second horizontal section of the second spacer extends laterally from the second vertical section towards the first vertical section of the first spacer, e.g., see FIG. 1A. There may be more than one instances of such first and second horizontal sections. In an example where the previously discussed second sacrificial material was only partially removed, the first horizontal section and the second horizontal section are not conjoined, e.g., laterally separated by a metal of the gate electrode (e.g., see FIG. 1A) or laterally separated by a dielectric material of an isolation region that is vertically between an upper gate electrode and a lower gate electrode (e.g., in a split gate architecture of FIG. 1C). In another example where the previously discussed second sacrificial material was fully removed, the first horizontal section and the second horizontal section are conjoined to form a continuous horizontal section extending laterally from the first vertical section to the second vertical section, e.g., see FIG. 2A. In this latter case, the first and second spacers can be thought of as one spacer structure.

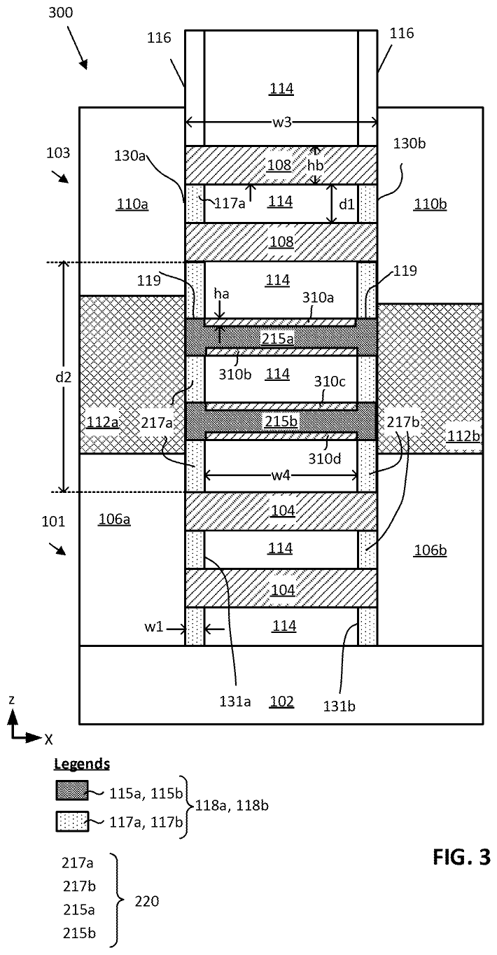

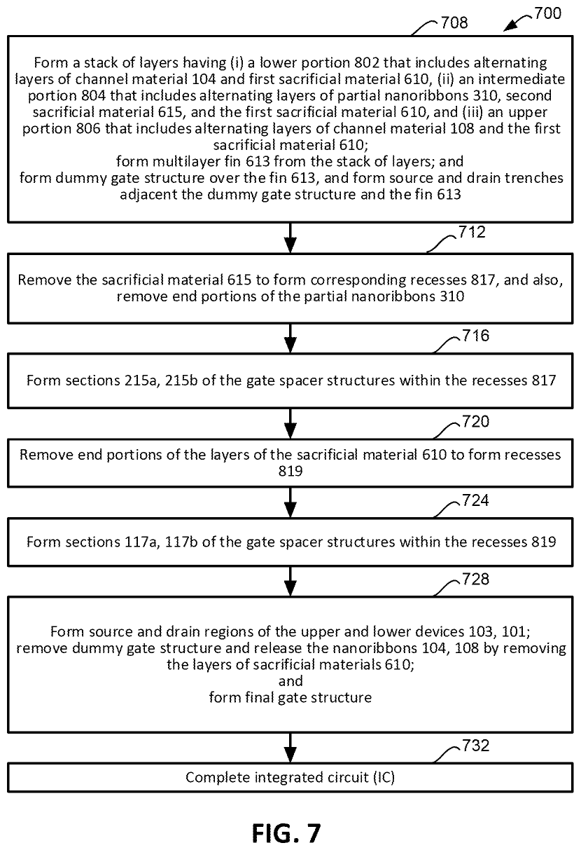

For the above discussed scenario of the continuous horizontal section extending laterally from the first vertical section to the second vertical section, in some embodiments, one or more partial nanoribbons comprising semiconductor material may be adjacent to the continuous horizontal section, e.g., see FIG. 3. For example, the partial nanoribbons may extend from the first vertical section and the second vertical section, and may not be in contact with any of the upper or lower source or drain regions. Similar to the horizontal sections, the partial nanoribbons are also within the distance d2 between the upper and lower nanoribbons of the upper and lower device. Further example details on the formation of the partial nanoribbons are provided with respect to method 700 of FIG. 7.

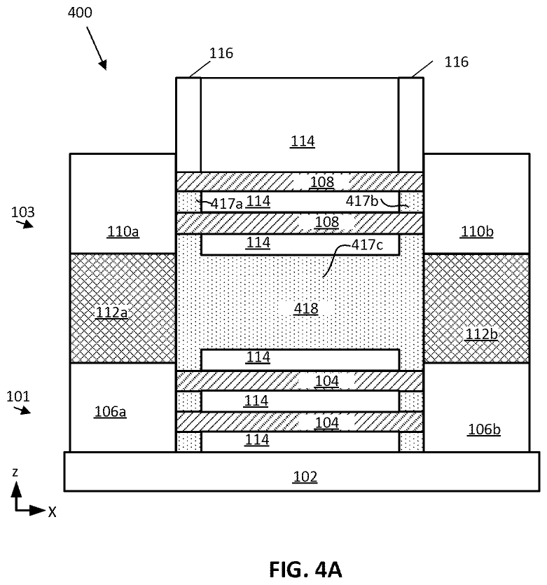

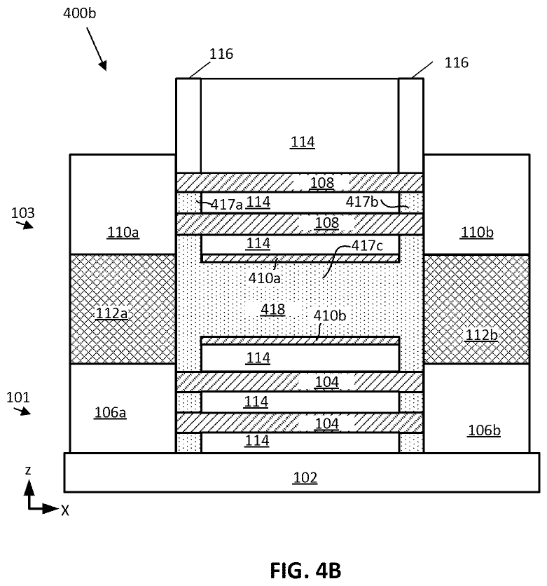

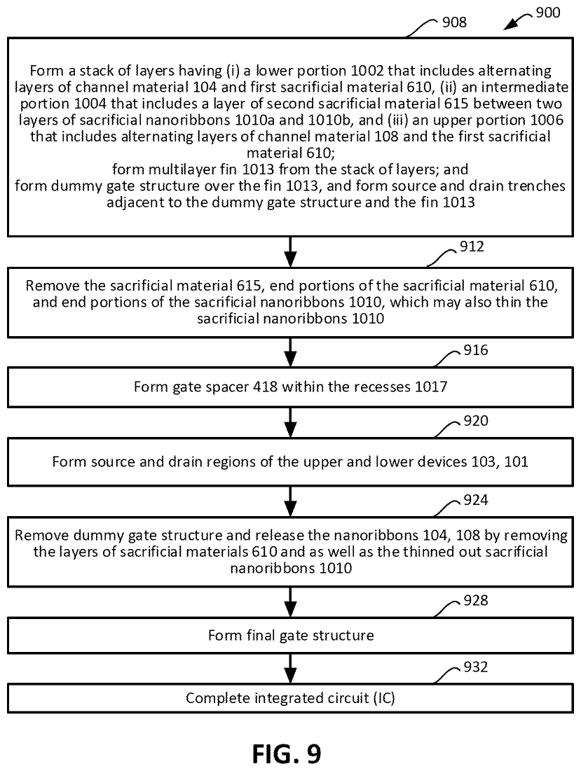

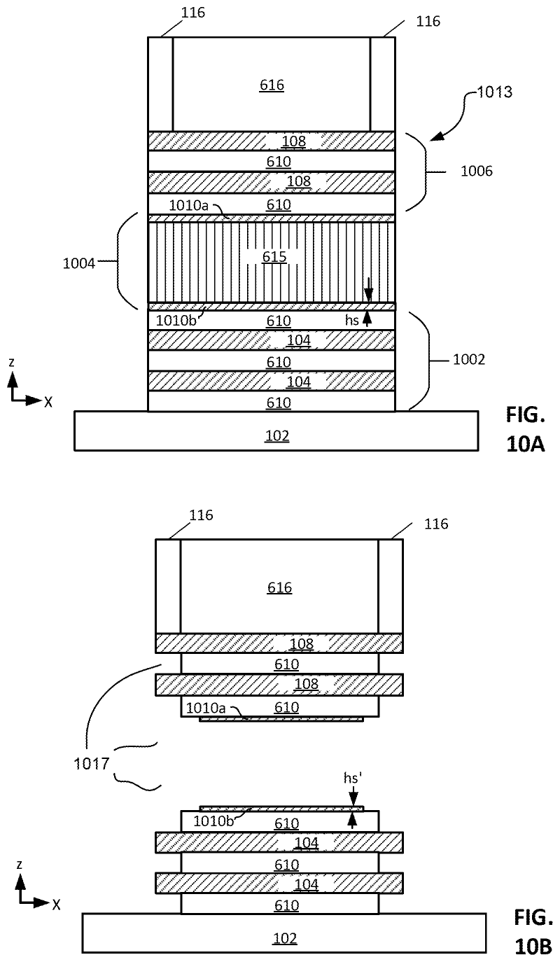

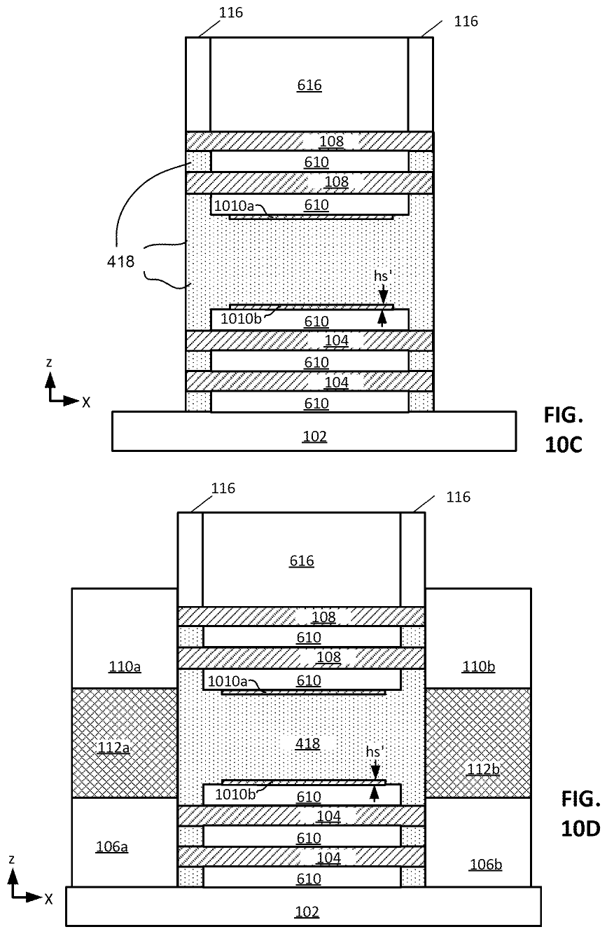

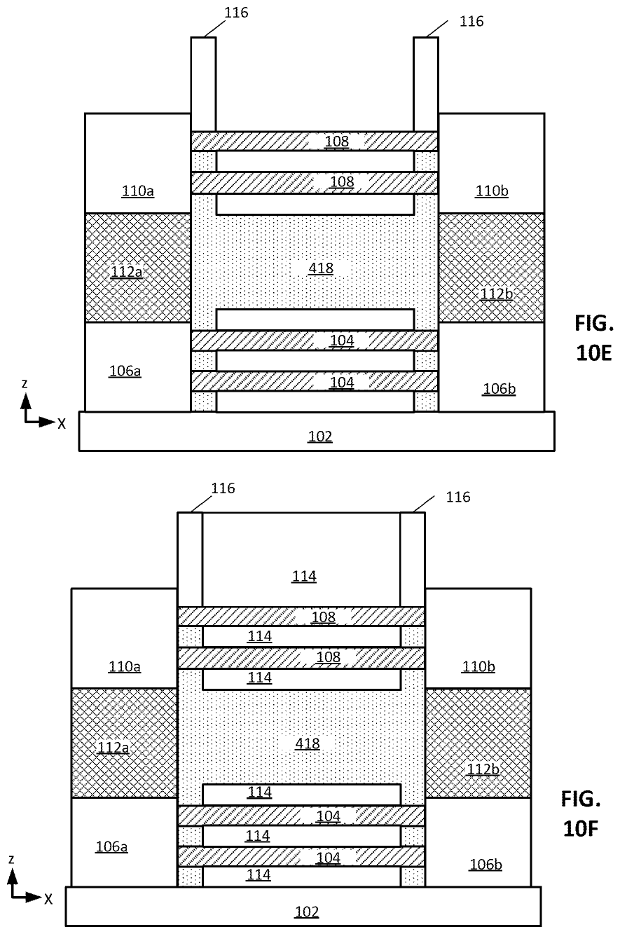

Note that there may be more than one horizontal sections between the upper and lower nanoribbons, e.g., as discussed herein with respect to FIGS. 1A-3, where a vertical height of each horizontal section may be comparable with (e.g., within 3 nm, or 2 nm, or 1 nm) of a vertical height of individual upper or lower nanoribbons. In contrast, as discussed herein later with respect to FIG. 4, a relatively thick continuous horizontal section between the two vertical sections may also be provided, where the horizontal section may be at least 1.5 times, or 2 times, or 3 times, or 4 times a vertical height of individual upper or lower nanoribbons. To form the thick horizontal section of FIG. 4, the previously discussed second sacrificial material in the intermediate portion of the fin is fully removed. Note that sacrificial nanoribbons may be above and below the second sacrificial material, e.g., see FIGS. 10A and 10B. Subsequently, end portions of the first sacrificial material may be removed. Subsequently, the recesses formed by removal of the second sacrificial material and the end portions of the first sacrificial material are filled with dielectric material, to form the gate spacers. Note that the entire gate spacer in this example is formed in a single deposition process, and hence, no seam or interface may be present within the horizontal and vertical sections of the gate spacers. Formation of such a gate spacer have been discussed in detail with respect to method 900 of FIG. 9.

Note that while in some examples the first and second sacrificial materials are removed to release the nanoribbons, in some other examples (e.g., in electrostatic discharge (ESD) diodes and/or some analog devices), the sacrificial materials are not removed (e.g., the nanoribbons are not released). In some such examples, the final device comprises the stack including the first and second sacrificial materials along with the channel materials, where various example fin stacks have been as discussed herein with respect to methods 500, 700, and 900.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In some embodiments, for instance, such tools be used to detect an upper GAA device stacked above a lower GAA device, where the device stack has a gate spacer structure comprising a horizontal section and a vertical section, wherein lateral dimensions of the horizontal and vertical sections vary (like a corrugated structure or other such structure having a non-linear sidewall, as viewed in cross-section profile). In an example, there may be two vertical sections of two gate spacers (where a first vertical section is adjacent to an upper source and lower source regions, and a second vertical section is adjacent to an upper drain and lower drain regions), and the horizontal section is laterally between the two vertical sections. In one example, the horizontal section extends laterally from the first vertical section to the second vertical section. In some examples, a partial nanoribbon comprising semiconductor material may be adjacent to the horizontal section of the gate spacer structure. In some examples (such as examples in which sacrificial materials are not removed to release the nanoribbons, such as in ESD diodes), a fin stack comprising first and second sacrificial materials along with channel materials for the upper and lower nanoribbons (and in some cases partial nanoribbons) may also be detected by such tools. Numerous configurations and variations will be apparent in light of this disclosure.

Architecture

FIG. 1A is a cross-sectional view of a portion of an integrated circuit structure 100 (also referred to herein as structure “100”) that includes a lower device 101, and an upper device 103 stacked vertically over the lower device 101, where a section of a gate spacer structure 118a of the integrated circuit structure 100 has (i) a first section 117a having a first dimension w1 in the lateral or X-axis direction, and (ii) a second section 115a having a second dimension w2 in the lateral or X-axis direction, wherein the first dimension w1 is different from the second dimension w2 by at least 1 nm, according to an embodiment of the present disclosure. The cross-section view of FIG. 1A is taken lengthwise (e.g., perpendicular to gate structure) across the devices 101, 103 in a first direction, while the devices 101, 103 are vertically stacked over one another in a second direction orthogonal to the first direction.

Semiconductor bodies 104 and 108 included in the channel regions of the devices 101 and 103, respectively, can vary in form, but in this example embodiment are in the form of nanoribbons. In particular, the channel region of the lower device 101 in this example case include a first set of two nanoribbons 104, and the channel region of the upper device 103 include a second set of two nanoribbons 108. Other examples may include fewer nanoribbons per channel region (e.g., one), or more nanoribbons per channel region (e.g., three, four, or higher). Still other embodiments may include other channel configurations, such as one or more nanowires, or nanosheets, or other appropriate GAA channel region. Yet other embodiments may include a fin-on-fin configuration, in which a fin of the upper device is above a fin of the lower device. Thus, each of devices 101 and 103 may be a GAA transistor, although other transistor topologies and types could also benefit from the techniques provided herein. Devices 101 and 103 represent a portion of integrated circuit structure 100 that may contain any number of similar semiconductor devices.

As can be seen, the devices 101 and 103 are formed over a substrate 102. Any number of semiconductor devices can be formed in a stacked configuration over the substrate 102, but two are used here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used.

Lower device 101 may include any number of nanoribbons 104 (such as two nanoribbons 104 illustrated in FIG. 1A) extending laterally (e.g., in the X axis direction) from a lower source region 106a to a lower drain region 106b. Likewise, upper device 103 may include any number of nanoribbons 108 (such as two nanoribbons 108 illustrated in FIG. 1A) extending laterally (e.g., in the X axis direction) from an upper source region 110a to an upper drain region 110b. Any source region may also act as a drain region and vice versa, depending on the application. In some embodiments, the devices 101 and 103 have an equal number of nanoribbons, while in other embodiments the two devices may have an unequal number of nanoribbons. In some embodiments, each of nanoribbons 104 and nanoribbons 108 are formed from a fin of alternating material layers (e.g., alternating layers of silicon and silicon germanium) where sacrificial material layers are removed between nanoribbons 104 and nanoribbons 108. Each of nanoribbons 104 and nanoribbons 108 may include the same semiconductor material as substrate 102, or not. In still other cases, substrate 102 is removed. In some such cases, there may be, for example one or more backside interconnect and/or contact layers.

According to some embodiments, an isolation region 112a is provided between the stacked upper and lower source regions 110a, 106a, and another isolation region 112b is provided between the stacked upper and lower drain regions 110b, 106b. Isolation regions 112a, 112b may comprise any suitable non-conductive material or dielectric material, such as silicon dioxide, aluminum oxide, silicon nitride, silicon oxycarbonitride, or one or more other appropriate oxides, nitrides, carbides, oxynitrides, oxycarbides, and/or oxycarbonitrides. In still other embodiments, layers 112a, 112b may be or otherwise include an air gap or void.

According to some embodiments, one or more (e.g., each) of source regions 106, 110a and drain regions 106b, 110b are epitaxial regions that are provided using an etch-and-replace process. In other embodiments one or both of the source regions 106a/110a and drain regions 106b/110b could be, for example, implantation-doped native portions of the semiconductor nanoribbons, fins or substrate. Any semiconductor materials suitable for source and drain regions can be used (e.g., group IV and group III-V semiconductor materials). The source regions 106a, 110a and drain regions 106b, 110b may include multiple layers such as liners and capping layers to improve contact resistance. In any such cases, the composition and doping of the source and drain regions may be the same or different, depending on the polarity of the transistors. Any number of source and drain configurations and materials can be used.

The source and drain regions can be any suitable semiconductor material and may include any dopant scheme. In an example, for instance, one transistor is a p-type MOS (PMOS) transistor, and the other transistor is an n-type MOS (NMOS) transistor. In an example, source and drain regions of a device (e.g., one of the upper or lower devices 101, 140) can be PMOS source and drain regions that include, for example, group IV semiconductor materials such as silicon, germanium, SiGe, germanium tin (GeSn), SiGe alloyed with carbon (SiGe:C). Example p-type dopants include boron, gallium, indium, and aluminum. Source and drain regions of another device (e.g., the other of the upper or lower devices 101, 140) can be NMOS source and drain regions that include, for example, silicon or group III-V semiconductor materials such as two or more of indium, aluminum, arsenic, phosphorus, gallium, and antimony, with some example compounds including but not limited to indium aluminum arsenide, indium arsenide phosphide, indium gallium arsenide, indium gallium arsenide phosphide, gallium antimonide, gallium aluminum antimonide, indium gallium antimonide, or indium gallium phosphide antimonide. Example n-type dopants include phosphorus, bismuth, antimony, arsenic, lithium, and tellurium. In one specific embodiment, PMOS source and drain regions are boron-doped SiGe, and NMOS source and drain regions are phosphorus-doped silicon. In a more general sense, the source and drain regions can be any semiconductor material suitable for a given application.

A gate structure 121 is provided over each of nanoribbons 104 and nanoribbons 108, according to some embodiments. For example, an upper gate structure wraps around middle section of individual nanoribbons 108 of the upper device 103, and a lower gate structure wraps around middle sections of individual nanoribbons 104 of the lower device 101, where each of the upper and lower gate structures are labelled generally as 121. Gate structure 121 includes both a gate dielectric 120 around each of nanoribbons 104 and nanoribbons 108, and a gate electrode 114 over the gate dielectric 120. The gate dielectric 120 is illustrated (with thick bolded lines) in an expanded view of a section 149 of the structure 100 of FIG. 1A. In an example, the gate dielectric material 120 warps around middle section of individual nanoribbons 104, 108 (note that end sections of individual nanoribbons are wrapped around by the gate spacer structures 118a, 118b). The gate dielectric material 120 is between individual nanoribbons and corresponding gate electrode, as illustrated. In an example, due to conformal deposition of the gate dielectric material 120, the gate dielectric material 120 may also be on inner sidewalls of the gate spacers 118a, 118b, as illustrated in the expanded view of the section 149 of the structure 100 of FIG. 1A.

The gate dielectric 120 may include a single material layer or multiple stacked material layers. The gate dielectric may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 120 is lanthanum. In some embodiments, the gate dielectric can be annealed to improve its quality when high-k dielectric material is used. In some embodiments, the gate dielectric 120 includes a first layer (e.g., native oxide of nanoribbons, such as silicon dioxide or germanium oxide or SiGe-oxide) on the nanoribbons, and a second layer of high-k dielectric (e.g., hafnium oxide) on the first layer.

An upper portion of the gate electrode 114, which is wrapped around the nanoribbons 108, is referred to as the upper gate electrode of the upper gate structure; and a lower portion of the gate electrode 114, which is wrapped around the nanoribbons 104, is referred to as the lower gate electrode of the lower gate structure. In the example of FIG. 1A, the upper gate electrode of the upper device 103 and the lower gate electrode of the lower device 101 form the continuous and monolithic body of gate electrode 114 (although a gate isolation structure may separate the lower and upper gate electrodes in other examples discussed herein below with respect to FIG. 1C). A middle portion of the gate electrode 114 may be assumed to be separate from each of the upper and lower gate electrodes, or may be assumed to be part of any (or both) of the upper or lower gate electrodes.

According to some embodiments, the gate electrode 114 extends over the gate dielectric 120 around each of nanoribbons 104 and nanoribbons 108 and also generally fills the remaining space between the various nanoribbons of any number of stacked semiconductor devices. The gate electrode 114 may include any sufficiently conductive material such as a metal, metal alloy, or doped polysilicon. In some embodiments, the gate electrode includes one or more workfunction metals around nanoribbons 104 and 108. In some embodiments, the device 101 is a p-channel device that includes n-type dopants within nanoribbons 104 and includes a workfunction metal having titanium around nanoribbons 104, and the device 103 is an n-channel device that includes p-type dopants within nanoribbons 108 and includes a workfunction metal having tungsten around nanoribbons 108. N-type dopants may also be used within the nanoribbons of an n-channel device and p-type dopants may be used within the nanoribbons of a p-channel device in order to tune the transistor's threshold voltage. Thus, upper portion of the gate electrode 114 (which may be the upper gate electrode) may include a first workfunction metal around nanoribbons 108 of the upper device 103, while lower portion of the gate electrode 114 (which may be the lower gate electrode) may include a second workfunction metal around nanoribbons 104 of the lower device 101. The gate electrode 114 may also include a fill metal or other conductive material around the workfunction metals to provide the whole gate electrode structure. According to some embodiments, the gate structure may be interrupted between any adjacent semiconductor devices by a gate cut structure.

Insulating layer 116 on both sides of a top portion of the gate electrode 114 allows for a planarized structure, such that the top surface of gate electrode 114 is co-planar with the top surface of insulating layer 116. Insulating layer 116 may comprise any suitable dielectric material.

As discussed above, in an example, the device 101 may be a p-channel device having semiconductor nanoribbons 104 doped with n-type dopants (e.g., phosphorous or arsenic) and semiconductor device 103 may be an n-channel device having semiconductor nanoribbons 108 doped with p-type dopants (e.g., boron), although in another example the devices 103 and 101 may be a p-channel and an n-channel device, respectively. Each of the devices 101 and 103 are separated by a vertical distance that is larger than the distance between adjacent nanoribbons. For example, a distance between adjacent nanoribbons of a same device (such as two adjacent nanoribbons 108 or two adjacent nanoribbons 104) is d1, and a distance between the sets of nanoribbons 108 and the sets of nanoribbons 104 is d2, as illustrated in FIG. 1A. As illustrated, the distances d1 and d2 are along a vertical or Z-axis direction, and are in a direction perpendicular to a length of the nanoribbons 104, 108 in the lateral or X-axis direction. In an example, the distance d1 is in the range of 2-12 nm, or in the subrange of 2-10 nm, 2-8 nm, 2-5 nm, 5-12 nm, 5-10 nm, 5-8 nm, 7-12 nm, or another appropriate subrange thereof. In an example, the distance d2 is in the range of 10-80 nanometers (nm), or in the subrange of 10-60 nm, 10-40 nm, 10-30 nm, 10-20 nm, 20-80 nm, 20-60 nm, 20-40 nm, 20-30 nm, 25-60 nm, 25-50 nm, or another appropriate subrange thereof.

In one embodiment, a first gate spacer structure 118a is on one side (e.g., the left side in FIG. 1A) and gate spacer structure 118b is included on another side (e.g., the right side in FIG. 1A) of the gate structure 121. For example, the gate spacer structure 118a separates the gate electrode 114 from the upper source region 110a, the lower source region 106a, and the isolation region 112a. Similarly, the gate spacer structure 118b separates the gate electrode 114 from the upper drain region 110b, the lower drain region 106b, and the isolation region 112b.

The gate spacer structure 118a has a first section 117a and a second section 115a, and similarly, the gate spacer structure 118b has a first section 117b and a second section 115b. In FIG. 1A, the sections 117a, 117b are illustrated using dotted areas, and the sections 115a, 115b are illustrated using grey areas. The sections 117a, 117b are referred to herein as vertical sections, as they extend vertically along the Z-axis, e.g., perpendicular to the length of the nanoribbons 104, 108. Similarly, the sections 115a, 115b are referred to herein as horizontal sections, as they extend horizontally along the X-axis, e.g., parallel to the nanoribbons 104, 108.

As illustrated, each of the sections 115a and 115b extend within the gate electrode 114. For example, as discussed herein above, an upper portion of the gate electrode 114 (e.g., which is wrapped around the nanoribbons 108) is referred to as the upper gate electrode of the upper gate structure; and a lower portion of the gate electrode 114 (e.g., which is wrapped around the nanoribbons 104) is referred to as the lower gate electrode of the lower gate structure. A middle portion of the gate electrode 114 may be assumed to be separate from each of the upper and lower gate electrodes, or may be assumed to be part of any (or both) of the upper or lower gate electrodes. The sections 115a and 115b extend within the middle portion of the gate electrode 114, as illustrated. Thus, the sections 115a and 115b may be assumed to extend between the upper and lower gate electrodes, or may be assumed to extend within any or both the upper and lower gate electrodes. In an example, the sections 115a and 115b extend within conductive material (e.g., metal) of the gate electrode 114.

In an example, the gate spacer structure 118a has (i) an outer sidewall 130a facing the source regions 110a, 106a and the isolation region 112a, and (ii) an inner sidewall 131a facing the gate electrode 114. Similarly, the gate spacer structure 118b has (i) an outer sidewall 130b facing the drain regions 110b, 106b and the isolation region 112b, and (ii) an inner sidewall 131b facing the gate electrode 114.

An entirety of the outer sidewall 130a of the gate spacer structure 118a is substantially coplanar, e.g., does not have any substantial peaks and valleys, or irregularities. Similarly, an entirety of the outer sidewall 130b is substantially coplanar, e.g., does not have any substantial peaks and valleys, or irregularities. For example, assume a first portion of the outer sidewall 130a that is within the section 117a and a second portion of the outer sidewall 130a that is within the section 115a. In an example, the first portion and the second portion are substantially coplanar, e.g., within 1 nm of each other. For example, a vertical plane of the first portion and a vertical plane of the second portion laterally coincides, or is separated laterally by at most 1 nm.

In contrast, the inner sidewall 131a (and also inner sidewall 131b) has irregularities, such as peaks and valleys (e.g., has a crenelated or corrugated pattern). For example, the inner sidewall 131a within the sections 115a extends within the gate electrode 114. Thus, portions of the inner sidewall 131a within the sections 115a are not coplanar with portions of the inner sidewall 131a within the sections 117a. The sections 115a may be periodically located along the vertical length of gate spacer structure 118a between the nanoribbons 104, 108.

For example, assume a first portion of inner sidewall 131a that is within the section 117a and a second portion of the inner sidewall 131a that is within the section 115a. In an example, the first portion and the second portion are not coplanar, e.g., separated by at least 1 nm, or at least 2 nm, or at least 5 nm from each other. For example, a vertical plane of the first portion and a vertical plane of the second portion is separated laterally by at least 1 nm, or at least 2 nm, or at least 5 nm. The inner sidewalls 131b also has a similar profile.

The gate spacer structure 118a is discussed herein below in further detail. Note that the structure of the gate spacer structure 118b is substantially similar to that of the gate spacer structure 118a (although a mirror image), and discussion with respect to gate spacer structure 118a also applies to the gate spacer structure 118b.

In an example, a dimension (e.g., width) of the sections 117a of the gate spacer structure 118a, along the horizontal X-axis direction (e.g., parallel to the nanoribbons 104, 108) is w1, as illustrated in FIG. 1A. In an example, a dimension (e.g., length) of the sections 115a of the gate spacer structure 118a, along the horizontal X-axis direction (e.g., parallel to the nanoribbons 104, 108) is w2, as illustrated in the expanded view of the section 149 in FIG. 1A. As illustrated, w2 is more than w1 in the example of FIG. 1A. For example, a difference between w2 and w1 is at least 1 nm, or at least 1.5 nm, or at least 2 nm, or at least 3 nm, or at least 4 nm, or at least 5 nm, or at least 6 nm, or at least 8 nm, or at least 10 nm. Thus, the sections 115a extend in parallel to the nanoribbons 104a, 104b, between (or within) the upper and lower gate electrode portions of the gate electrode 114.

In an example, the sections 115a are vertically between the upper nanoribbons 108 and the lower nanoribbons 104, e.g., within a portion of the gate spacer structure 118a that is between the upper nanoribbons 108 and the lower nanoribbons 104. For example, at least a portion of the upper gate electrode is above the sections 115a, and at least a portion of the lower gate electrode is below the sections 115a. Thus, the sections 115a are between at least a portion of the upper gate electrode and at least a portion of the lower gate electrode. In an example, the sections 115a of the gate spacer structure 118a wrap around an end section of each nanoribbon 104, 108, and also wrap around an end section of each section 117a.

In an example, and as illustrated in the expanded view of the section 149, due to conformal deposition of gate dielectric 120, the gate dielectric 120 are deposited on inner sidewall 131a of the gate spacer structure 118a. Accordingly, in an example, the gate dielectric 120 separates the gate spacer structure 118a from the gate electrode 114.

In an example, the sections 117a and the sections 115a are formed during respective deposition processes (e.g., as will be discussed herein below in turn). For example, the sections 115a are formed during a first deposition process, and the sections 117a are formed during a second deposition process that occurs subsequent to the first deposition process. Accordingly, an interface 119 (such as a seam or a grain boundary) may be formed between an interface of two adjacent sections 117a, 115a, as illustrated.

In an example, both sections 117a and 115a comprise dielectric material. In an example, the dielectric materials of the sections 115a, 117a can be elementally and/or compositionally same, or can be elementally and/or compositionally different. For example, the dielectric material of one of the sections 115a, 117b can be silicon nitride, and the dielectric material of the other of the sections 115a, 117b can be silicon dioxide. Sections 115a, 117b may include any appropriate dielectric material, such as silicon nitride, silicon oxynitride, silicon carbide, silicon oxycarbonitride, silicon dioxide, aluminum oxide, or another appropriate nitride, oxide, carbide, oxycarbide, oxynitride, or oxycarbonitride, or low-K versions (e.g., porous or doped) of any of these that can provide electrical isolation between gate electrode 114 and the source or drain regions.

As illustrated, there are two instances of the sections 115a (e.g., upper section 115a and lower section 115a), and two instances of the sections 115b (e.g., upper section 115b and lower section 115b), although one, three, or higher instances of each of sections 115a, 115b may be present.

In an example, the upper section 115a and the upper section 115b are coplanar. For example, both the upper section 115a and the upper section 115b are formed by removing a single layer of sacrificial material 615 (as will be discussed herein below with respect to FIGS. 6D and 6E), and hence, the upper section 115a and the upper section 115b are coplanar. For example, upper surfaces of the upper section 115a and the upper section 115b are coplanar, and similarly, lower surfaces of the upper section 115a and the upper section 115b are coplanar. Similarly, the lower section 115a and the lower section 115b are also coplanar.

As illustrated, the upper section 115a and the upper section 115b are laterally separated by the gate electrode 114, and the lower section 115a and the lower section 115b are also laterally separated by the gate electrode 114.

In an example, the gate spacer structure 118a may be assumed to include (i) an upper portion (e.g., an upper portion of the section 117a) adjacent to the upper source region 110a, (ii) a lower portion (e.g., a lower portion of the section 117a) adjacent to the lower source region 106a, and (iii) an intermediate portion (e.g., comprising an intermediate upper portion of the section 117a and also the sections 115a) adjacent to the isolation region 112a. Thus, the upper portion of the gate spacer structure 118a separates the upper source region 110a from the upper gate stack, the lower portion of the gate spacer structure 118a separates the lower source region 106a from the lower gate stack, and the intermediate portion of the gate spacer structure 118a at least in part extends laterally within at least one of the upper and lower gate structures, or extends between the upper and lower gate structures.

FIG. 1B is a cross-sectional view of a portion of an integrated circuit structure 100b (also referred to herein as structure “100b”) that is at least in part similar to the integrated circuit structure 100a of FIG. 1A, wherein the gate spacer structures 118 in FIG. 1B have a different profile compared to that in FIG. 1A, according to an embodiment of the present disclosure. Similar components of FIGS. 1A and 1B are labelled similarly. In FIG. 1A, the sections 115a (and 115b) extended within the gate electrode 114, and the width w2 of the section 117a was more than the width w1 of the section 115a. In contrast, in FIG. 1B, a width w4 of the sections 117a is less than the width w1 of the section 117a, where the widths are measured along the horizontal X-axis and parallel to the length of the nanoribbons 104, 108.

FIG. 1C is a cross-sectional view of a portion of an integrated circuit structure 100c (also referred to herein as structure “100c”) that is at least in part similar to the integrated circuit structure 100a of FIG. 1A, wherein in FIG. 1C an isolation structure 140 separates an upper gate electrode 114a of the upper device 103 from a lower gate electrode 114b of the lower device 101, according to an embodiment of the present disclosure. Similar components of FIGS. 1A and 1C are labelled similarly. In FIG. 1A, a continuous and monolithic body of conductive material, e.g., gate electrode 114, is wrapped around nanoribbons 104 and 108 of both the upper and lower devices. In contrast, FIG. 1C illustrates an example of a split-gate configuration. In particular, upper gate electrode 114a wraps around the nanoribbons 108, and lower gate electrode 114b wraps around the nanoribbons 104. An isolation structure 140 is between and separates the upper and lower gate electrodes 114a, 114b. The previous relevant discussion for each of the depicted features is equally applicable here. Note that the upper gate structure may be configured differently from the lower gate structure, or the same. In one example case, the upper gate structure and the lower gate structure include the same gate dielectric 120, but include different workfunction materials in their respective gate electrodes. For instance, one of the upper or lower gate electrode may include a p-type workfunction material (e.g., titanium nitride) and the other of the upper or lower gate electrode may include an n-type workfunction material (e.g., titanium aluminum carbide). The isolation structure 140 can be any suitable dielectric material, such as silicon oxide, and may be the same or different material, for instance, as gate spacer structures 118a, 118b.

As illustrated, in the example of FIG. 1C, the sections 115a, 115b extend within the isolation structure 140, e.g., between the upper and lower gate electrodes 114a, 114b. Furthermore, an upper section 115a and an upper section 115b are laterally separated by the dielectric material of the isolation structure 140.

FIG. 2A is a cross-sectional view of a portion of an integrated circuit structure 200 (also referred to herein as structure “200”) that includes a lower device 101, an upper device 103 stacked vertically over the lower device 101, a first gate spacer structure 217a and a second gate spacer structure 217b, and one or more dummy nanoribbons 215a, 215b (also referred to as structures 215a, 215b) comprising dielectric material extending from isolation region 112a to isolation region 112b and between the first gate spacer structure 217a and the second gate spacer structure 217b, according to an embodiment of the present disclosure. Similar components of FIGS. 1A and 2A are labelled similarly, and discussion of various components of FIG. 1A, unless contradictory or otherwise mentioned, are also applicable to FIG. 2A.

In FIG. 1A, the sections 115a and 115b extends partially within the gate electrode 114. In contrast, in FIG. 2, each structure 215 extends from the first gate spacer structure 217a to the second gate spacer structure 217b. Note that the gate spacer structures 217a, 217b are similar to the sections 117a, 117b of FIG. 1A, and the structure 215a, 215b are similar to the sections 115a, 115b of FIG. 1A. However, in FIG. 1A, the sections 115a, 115b were not conjoined. In contrast, in FIG. 2A, each structure 215 extends fully from the gate spacer structure 217a to the second gate spacer structure 217b. In an example, each of the structures 215 is parallel to the nanoribbons 104, 108, e.g., extending in the horizontal X-axis direction. As illustrated, a length of each structure 215 may be about the same as a length w3 of individual nanoribbons 104, 108. In an example, distance w3 is more than distance w1 by at least 4 nm, or at least 5 nm, or at least 6 nm, or at least 8 nm, or at least 10 nm.

As illustrated, the gate spacer structure 217a is above and below (and at least in part wraps around) a first end of the structures 215a, 215b, and the gate spacer structure 217b is above and below (and at least in part wraps around) a second end of the structures 215a, 215b. As discussed with respect to FIG. 1A, in an example, the dielectric material of the gate spacer structures 217a, 217b and the dielectric material of the structures 215a, 215b may be elementally and/or compositionally similar or different. In an example, the gate spacer structures 217a, 217b and the structures 215a, 215b form a continuous gate spacer structure 220, as symbolically illustrated in the legends section of FIG. 2A.

The example of FIG. 2A illustrates the structures 215 extending through the gate electrode 114. However, in another example, the structures 215 may at least in part extend through an isolation structure that separates upper and lower gate electrodes, such as the isolation structure 140 of FIG. 1C. Although two instances of the structures 215 (e.g., 215a, 215b) are illustrated, the integrated circuit structure 200 may include one, three, or higher instances of the structures 215.

Note that in FIG. 2B, the continuous gate structure 200 has outer sidewalls 130a and 130b, similar to those in FIG. 1A. The continuous gate structure 200 has an inner sidewall 131a, and a portion of the inner sidewall 131a (e.g., which is included within the structure 215a or 215b) coincides with a corresponding portion of the outer sidewall 130b. Similarly, the continuous gate structure 200 has an inner sidewall 131b, and a portion of the inner sidewall 131b (e.g., which is included within the structure 215a or 215b) coincides with a corresponding portion of the outer sidewall 130a.

In FIG. 2A, the structures 215 are dummy nanoribbons (e.g., comprising dielectric material) extending laterally from one isolation region 112a to another isolation region 112b. However, in another example, one or both the structures 215 may also at least in part extend from an upper (or lower) source region to an upper (or lower) drain region, as illustrated in FIG. 2B. For example, FIG. 2B is a cross-sectional view of a portion of an integrated circuit structure 200b (also referred to herein as structure “200b”) that is at least similar to the integrated circuit structure 200 of FIG. 2A, and wherein in FIG. 2B at least a part of a structure 215 comprising dielectric material extends laterally between an upper (or lower) source region and an upper (or lower) drain region, according to an embodiment of the present disclosure. Similar components of FIGS. 2A and 2B are labelled similarly, and discussion of various components of FIGS. 1A and 2A, unless contradictory or otherwise mentioned, are also applicable to FIG. 2B. As illustrated, in FIG. 2B, the isolation structures 112a and 112b are smaller in size (e.g., compared to the size of the isolation structures in FIG. 2A), and hence, in FIG. 2B, at least a part of the structure 215a extends from the upper source region 110a to the upper drain region 110b. Although not illustrated, in an example, the structure 215b (or at least a part of the structure 215b) may also extend from the lower source region 106a to the lower drain region 106b.

FIG. 3 is a cross-sectional view of a portion of an integrated circuit structure 300 (also referred to herein as structure “300”) that includes a lower device 101, an upper device 103 stacked vertically over the lower device 101, a first gate spacer structure 217a and a second gate spacer structure 217b, one or more dummy nanoribbons 215a, 215b (also referred to as structures 215a, 215b) comprising dielectric material laterally extending between the first gate spacer structure 217a and the second gate spacer structure 217b, and partial nanoribbons 310 comprising semiconductor material above and/or below individual ones of the dummy nanoribbon structures 215a, 215b, according to an embodiment of the present disclosure. Similar components of FIGS. 1A, 2A, and 3 are labelled similarly, and discussion of various components of FIGS. 1A and 2A, unless contradictory or otherwise mentioned, are also applicable to FIG. 3.

As illustrated in FIG. 3, the gate spacer structure 217a is above and below (and at least in part wraps around) a first end of the structures 215a, 215b, and the gate spacer structure 217b is above and below (and at least in part wraps around) a second end of the structures 215a, 215b. As discussed with respect to FIG. 1A, in an example, the dielectric material of the gate spacer structures 217a, 217b and the dielectric material of the structures 215a, 215b may be elementally and/or compositionally similar or different, with an interface (e.g., a seam or grain boundary) 119 formed between adjacent structures 217 and 215. In an example, the gate spacer structures 217a, 217b and the structures 215a, 215b form a continuous gate spacer structure 220, as symbolically illustrated in the legends section of FIG. 3A.

As illustrated, the partial nanoribbons 310a, 310b, 310c, and 310d extend laterally in a horizontal X-axis direction, e.g., parallel to the nanoribbons 104, 108. In an example, a height ha of each partial nanoribbons 310 (e.g., measured in the vertical Z-axis direction) is substantially less than a height hb of each nanoribbon 104, 108 (e.g., measured in the vertical Z-axis direction). For example, height ha may be less than height hb by at least 1 nm, or at least 2 nm, or at least 3 nm, or at least 4 nm, or at least 5 nm, or at least 6 nm, or at least 7 nm, or at least 8 nm, for example.

The nanoribbons 310a, 310b, 310c, and 310d are partial nanoribbons, as they don't contact the upper or lower source regions, and/or upper or lower drain regions (or even don't contact the isolation regions 12a, 112b). Rather, the partial nanoribbons 310a, 310b, 310c, and 310d extend between the gate spacer structures 217a and 217b. For example, unlike the nanoribbons 104, 108, end portions of the partial nanoribbons 310 are not wrapped around by the gate spacer structures 217a or 217b. Accordingly, a length w4 of the partial nanoribbons 310 is less than the length w3 of the nanoribbons 104, 108, as illustrated in FIG. 3, where the lengths are measured in the horizontal X-axis direction. In an example, the partial nanoribbons 310 and the nanoribbons 104 and/or 108 may comprise same semiconductor material. However, in an example, the nanoribbons 104, 108 may be doped by one or more appropriate dopants (e.g., where the dopants for the nanoribbons 104 may depend on a type of the device 103, and where the dopants for the nanoribbons 108 may depend on a type of the device 101). In an example, he partial nanoribbons 310 may be undoped, or doped similar to the nanoribbons 104 and/or similar to the nanoribbons 108.

The example of FIG. 3 illustrates the structures 215 and the partial nanoribbons 310 extending through the gate electrode 114. However, in another example, the structures 215 and the partial nanoribbons 310 may at least in part extend through an isolation structure that separates upper and lower gate electrodes, e.g., similar to the isolation structure 140 of FIG. 1C.

FIG. 4A is a cross-sectional view of a portion of an integrated circuit structure 400 (also referred to herein as structure “400”) that includes a lower device 101, an upper device 103 stacked vertically over the lower device 101, and a continuous and monolithic gate spacer structure 418 that comprises (i) a first vertical section 417a adjacent to the source regions 110a, 106a of the upper and lower devices 103, 101, (ii) a second vertical section 417b adjacent to the drain regions 110b, 106b of the upper and lower devices 103, 101, and (iii) a horizontal section 417c extending laterally from the first vertical section 417a to the second vertical section 417b, according to an embodiment of the present disclosure. Similar components of FIGS. 1A and 4 are labelled similarly, and discussion of various components of FIG. 1A, unless contradictory or otherwise mentioned, are also applicable to FIG. 4A.

As illustrated, the gate spacer structure 418 comprises the first vertical section 417a, the second vertical section 417b, and the horizontal section 417c conjoining the vertical sections 417a, 417b. The vertical section 417a is between the gate electrode 114 and the upper and lower source regions 110a, 106a, and the vertical section 417b is between the gate electrode 114 and the upper and lower drain regions 110b, 106b. Note that in an example, the gate electrode 114 may be a split gate electrode, e.g., split in an upper gate electrode for the upper device 103 and a lower gate electrode for the lower device 101, e.g., as discussed with respect to FIG. 1C herein earlier. In another example, the gate electrode 114 may not be split. In a split gate architecture, the horizontal section 417c is between the upper and lower gate electrodes.

In an example, the vertical section 417a, the vertical section 417b, and the horizontal section 417c of the gate spacer structure 418 are formed during a same deposition process (e.g., discussed with respect to FIG. 10C herein below). Accordingly, the vertical section 417a, the vertical section 417b, and the horizontal section 417c of the gate spacer structure 418 are continuous and monolithic, without any seam, interface, or grain boundary therebetween. In contrast, note the interface 119 in the structure 100 of FIG. 1A.

In an example, the vertical section 417a, the vertical section 417b, and the horizontal section 417c of the gate spacer structure 418 are elementally and/or compositionally same, and comprises the same dielectric material. In an example, the gate spacer structure 418 comprises an appropriate dielectric material, such as silicon nitride, silicon oxynitride, silicon carbide, silicon oxycarbonitride, silicon dioxide, aluminum oxide, or another appropriate nitride, oxide, carbide, oxycarbide, oxynitride, or oxycarbonitride, or low-K versions (e.g., porous or doped) of any of these that can provide electrical isolation between gate electrode 114 and the source or drain regions.

FIG. 4B is a cross-sectional view of a portion of an integrated circuit structure 400 (also referred to herein as structure “400”) that includes a lower device 101, an upper device 103 stacked vertically over the lower device 101, and a continuous and monolithic gate spacer structure 418 that comprises (i) a first vertical section 417a adjacent to the source regions 110a, 106a of the upper and lower devices 103, 101, (ii) a second vertical section 417b adjacent to the drain regions 110b, 106b of the upper and lower devices 103, 101, and (iii) a horizontal section 417c extending laterally from the first vertical section 417a to the second vertical section 417b, wherein the integrated circuit structure 400 further comprises partial nanoribbons 410a, 410b formed on an upper and/or lower surfaces of the horizontal section 417c of the gate spacer structure 418, according to an embodiment of the present disclosure. Similar components of FIGS. 4A and 4B are labelled similarly, and discussion of various components of FIG. 4A, unless contradictory or otherwise mentioned, are also applicable to FIG. 4B.

In one embodiment, the partial nanoribbons 410a, 410b comprise semiconductor material (e.g., same as the materials of the nanoribbons 104, 108) and may be at least in part similar to the partial nanoribbons 310 of FIG. 3, and discussions with respect to the partial nanoribbons 310 of FIG. 3 also applies to the partial nanoribbons 410 of FIG. 4B.

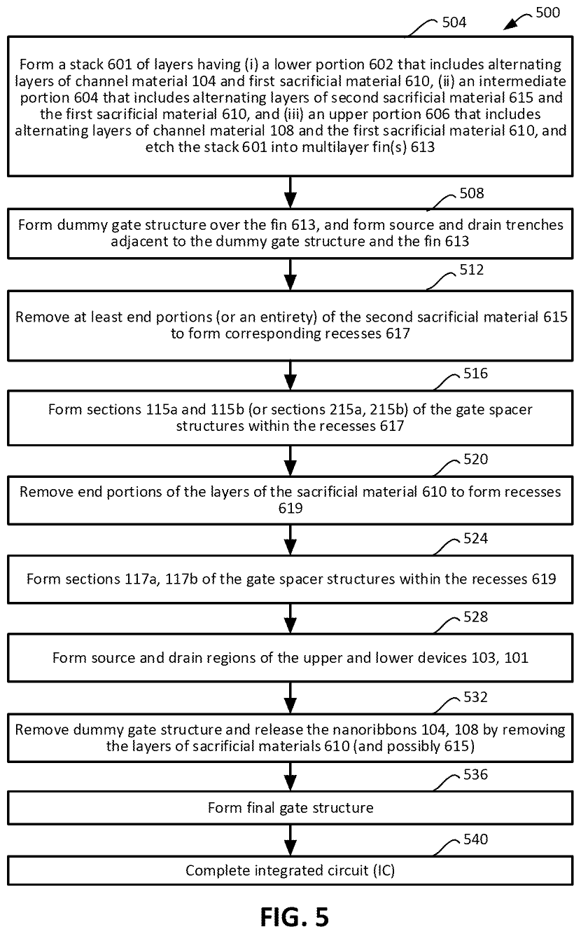

FIG. 5 illustrates a flowchart depicting a method 500 of forming any of the example integrated circuit structures 100 or 200 of FIG. 1A-1C or 2A-2B, in accordance with an embodiment of the present disclosure. FIGS. 6A, 6B, 6C, 6D, 6D1, 6E, 6E1, 6F, 6F1, 6G, 6G1, 6H, 6H1, 6I, 6I1, 6J, 6J1, 6K, and 6K1 collectively illustrate cross-sectional views of an example integrated circuit device semiconductor structure (e.g., the integrated circuit structures 100 or 200 of FIG. 1A-1C or 2A-2B) in various stages of processing, in accordance with an embodiment of the present disclosure. Specifically, FIGS. 6A, 6B, 6C, 6D, 6E, 6F, 6G, 6H, 6I, 6J, and 6K illustrate formation of the integrated circuit structure 100 of FIG. 1A, while FIGS. 6A, 6B, 6C, 6D1, 6E1, 6F1, 6G1, 6H1, 611, 6J1, and 6K1 illustrate formation of the integrated circuit structure 200 of FIG. 2A. FIGS. 5 and 6A-6K1 will be discussed in unison. The cross-sectional views of FIGS. 6A-6K1 correspond to the cross-sectional views of FIGS. 1A and 2A.

Referring to method 500 of FIG. 5, at 504, a stack 601 of layers is formed on a substrate 102, where the stack 601 comprises (i) a lower portion 602 that includes alternating layers of channel material 104 and first sacrificial material 610, (ii) an intermediate portion 604 that includes alternating layers of second sacrificial material 615 and the first sacrificial material 610, and (iii) an upper portion 606 that includes alternating layers of channel material 108 and the first sacrificial material 610, e.g., as illustrated in FIG. 6A. The stack 601 is then etched to form one or more multiplayer fins, such as fin 613 illustrated in FIG. 6B.

Note that the lower portion 602 of the stack 601 includes two layers of channel material 104 and the upper portion 606 of the stack 601 includes two layers of channel material 108. However, any number of layers of channel material 104, 108 may be used. Similarly, the number of layers of sacrificial material 615 is two in this example, although the number can be one, three, or higher.

In an example, the first sacrificial material 610 and second sacrificial material 615 are etch selective to each other, and to the channel materials 104, 108. For example, an etch process to etch the first sacrificial material 610 may not substantially etch the second sacrificial material 615 and the channel materials 104, 108. Similarly, an etch process to etch the second sacrificial material 615 may not substantially etch the first sacrificial material 610 and the channel materials 104, 108.

In one embodiment, sacrificial material 610 are compositionally different from the sacrificial material 615, contributing to the above discussed etch selectivity between the two sacrificial materials 610, 615. In one example, both sacrificial materials 610, 615 comprise silicon germanium (SiGe), but with a different percentage of germanium. For example, a percentage of germanium by atomic weight within the sacrificial material 615 may be higher (or lower) than a percentage of germanium by atomic weight within the sacrificial material 610. In one example, the sacrificial material 615 has germanium by atomic weight in the range of 20-35%, or in a subrange of 25-35%, or 30-35%, or 20-30%, or 20-26%, or 21-25%, or within another appropriate subrange thereof. In one example, the sacrificial material 610 has germanium by atomic weight in the range of 10-25%, or in a subrange of 10-20%, or 10-15%, or 15-25%, or 15-20%, or 12-18%, or within another appropriate subrange thereof. The difference in germanium content within the sacrificial materials 610, 615 results in the etch selectivity between the two sacrificial materials 610, 615. In another embodiment, one of the sacrificial materials 610, 615 is doped with a dopant, while the other of the sacrificial materials 610, 615 is undoped or doped with a different dopant, thereby resulting in the etch selectivity between the two sacrificial materials 610, 615.

The channel material 104 include one or more semiconductor materials suitable for use as nanoribbons 104 for the lower device 101, and the channel material 108 include one or more semiconductor materials suitable for use as nanoribbons 108 for the upper device 103. Examples of the channel materials 104, 108 may include silicon (Si), SiGe, germanium, or III-V materials like indium phosphide (InP) or gallium arsenide (GaAs), and maybe based on the type (e.g., PMOS or NMOS) of the upper and lower devices 101, 103.

While dimensions can vary from one example embodiment to the next, the thickness of each sacrificial layers 610, 615 may be between about 5 nm and about 10 nm. In some embodiments, the thickness of each sacrificial layer is substantially the same (e.g., within 1-2 nm) across each of lower portion 602, intermediate portion 604, and upper portion 606. The thickness of each of the layers of channel materials 104, 108 may be about the same as the thickness of each sacrificial layers 601, 615 (e.g., about 5-20 nm). Each of sacrificial layers 610, 615, and layers of channel materials 104, 108 may be deposited using any appropriate material deposition technique, such as chemical vapor deposition (CVD), plasma-enhanced chemical vapor deposition (PECVD), physical vapor deposition (PVD), or atomic layer deposition (ALD).

Layers of the channel materials 104 may be doped with either n-type dopants (to produce a p-channel transistor) or p-type dopants (to produce an n-channel transistor). Similarly, layers of the channel materials 108 may be doped with either n-type dopants (to produce a p-channel transistor) or p-type dopants (to produce an n-channel transistor).

Referring again to FIG. 5, the method 500 proceeds from 504 to 508, where a dummy gate structure 616 (e.g., along with sidewall spacers 116) is formed over the fin 613, e.g., as illustrated in FIG. 6C. The dummy gate structure 616 may run in an orthogonal direction to the length of the fin 613, and may include any material that can be safely removed later in the process without etching or otherwise damaging any portions of the fin or the sidewall spacer 116. In some embodiments, dummy gate structure 616 includes polysilicon. Sidewall spacer 116 may include a dielectric material, such as silicon nitride, silicon oxy-nitride, or any formulation of those layers incorporating carbon or boron dopants. In an example, the dummy gate structure is initially is blanket deposited over the previously-formed multilayer fin 613, and then a mask is patterned or formed where the gate structure is to be, and then the excess (e.g., unmasked portion) of the blanket gate materials are etched away, to leave the dummy gate structure that is orthogonal to the multilayer fin 613, as illustrate din FIG. 6C. Removal of the dummy gate structure and/or etching of the stack of layers (in process 504) results in formation of the source and drain recesses adjacent to the dummy gate structure and the fin 613.

Referring again to FIG. 5, the method 500 proceeds from 508 to 512, where at least end portions (see FIG. 6D), or an entirety (see FIG. 6D1), of the second sacrificial material 615 are removed, to form corresponding recesses 617. For example, FIG. 6D illustrates partial removal of the layers of sacrificial material 615 (which will result in eventual formation of the device 100 of FIG. 1A), whereas FIG. 6D1 illustrates full removal of the layers of sacrificial material 615 (which will result in eventual formation of the device 200 of FIG. 2A). The etching process may be timed and controlled, to result in either of the structures of FIG. 6D or 6D1. An isotropic etching process may be used to recess the exposed ends (or the entirety) of the layers of sacrificial material 615. As discussed, the etch process may be selective to the layers of sacrificial material 615, such that the layers of sacrificial material 610 and the layers of channel materials 104, 108 are not substantially etched. In an example, removal of at least portions of the layers of sacrificial material 615 results in recesses 617, as illustrated in FIGS. 6D and 6D1.

Referring again to FIG. 5, the method 500 proceeds from 512 to 516, where sections 115a and 115b (or sections 215a and 215b) of the gate spacer structures are formed within the recesses 617, as illustrated in FIGS. 6E1 and 6E2. For example, filing the recesses 617 of the structure of FIG. 6D with dielectric material results in formation of sections 115a, 115b of FIG. 6E. Filing the recesses 617 of the structure of FIG. 6D1 results in formation of sections 215a, 215b of FIG. 6E1. Dielectric material for the sections 115a, 115b (or 215a, 215b) have been discussed herein above. The dielectric material may be conformally deposited over the sides of the fin structure using CVD, ALD, or another appropriate deposition technique, and then etched back to form the coplanar sidewalls of FIGS. 6E and 6E1 (such that end portions of the layers of sacrificial material 610 and channel materials 104, 108 remain exposed).

Referring again to FIG. 5, the method 500 proceeds from 516 to 520, where the exposed end portions of the sacrificial material 610 are removed, to form corresponding recesses 619. For example, FIG. 6F illustrates removal of end portion of the layers of sacrificial material 610 of the structure of FIG. 6E, and FIG. 6F1 illustrates removal of end portion of the layers of sacrificial material 610 of the structure of FIG. 6E1. An appropriate selective etch process may be employed, which removes end portions of the layers of sacrificial material 610, without substantially etching the layers of sacrificial material 615 (in FIG. 6F), the dielectric material 115a, 115b (or 215a, 215b), and the layers of channel materials 104, 108.

Referring again to FIG. 5, the method 500 proceeds from 520 to 524, where sections 117a, 117b of the gate spacer structures are formed within the recesses 619. For example, dielectric material for the sections 117a, 117b of the gate spacer structures are deposited, as illustrated in FIGS. 6G and 6G1 (e.g., where the structure of FIG. 6G is formed from the structure of FIG. 6F, and where the structure of FIG. 6G1 is formed from the structure of FIG. 6F1). Subsequently, the sections 117a, 117b are etched back (e.g., using an isotropic etching process) to uniformly recess these sections. For example, the sections 117a, 117b are recessed inwards, at least until both ends of layers of the channel materials 104, 108 are exposed, as illustrated in FIGS. 6H and 6H1 (e.g., where the structure of FIG. 6H is formed from the structure of FIG. 6G, and where the structure of FIG. 6H1 is formed from the structure of FIG. 6G1). Note that along with the end of the layers of the channel materials 104, 108, the end of the sections 115a, 115b in FIG. 6H and the end of the sections 215a, 215b in FIG. 6H1 are also exposed.

Referring again to FIG. 5, the method 500 proceeds from 524 to 528, where the source region 110a and drain region 110b of the upper device 103, and the source region 106a and the drain region 106b of the lower device 101 are formed, as illustrated in FIGS. 6I and 6I1 (e.g., where the structures of FIGS. 6I and 6I1 are respectively formed from the corresponding structures of FIGS. 6H and 6H1). Note that isolation region 112a is formed between the upper and lower source regions, and isolation region 112b is formed between the upper and lower drain regions. In an example, the source and drain regions are formed epitaxially. In some examples, lower source and drain regions 106a, 106b are epitaxially grown over the substrate 102. The isolation regions 112a, 112b are formed above the source and drain regions 106a, 106b, respectively. Subsequently, upper source and drain regions 110a, 110b are epitaxially grown over the isolation regions 112a, 112b, respectively. Example materials and dopants for the various source and drain regions have been discussed herein above.

Referring again to FIG. 5, the method 500 proceeds from 528 to 532, where the dummy gate structure 616 is removed, and the nanoribbons 104, 108 are released by removing the layers of sacrificial material 610 (and sacrificial material 615 of FIG. 6I), e.g., as illustrated in FIGS. 6J and 6J1. The structures of FIGS. 6J and 6J1 are respectively formed from the corresponding structures of FIGS. 6I and 611. Note that in FIG. 611, the layers of sacrificial materials 615 already fully removed, and hence, in FIG. 6J1, only layers of sacrificial materials 610 are removed. In contrast, in FIG. 6J, layers of both sacrificial materials 610, 615 are removed.

In an example, the dummy gate structure 616 may be removed using any wet or dry isotropic process, thus exposing the alternating layer stack of the channel materials 104, 108 and the various layers of sacrificial materials (along with sections 115a, 116b or 215a, 215b). Once sacrificial gate structure 616 has been removed, the remaining sacrificial layers may also be removed using a selective isotropic etching process that removes the material of sacrificial layers, but does not remove (or removes very little of) channel materials 104, 108 and the sections 115a, 115b or 215a, 215b. At this point, the suspended (sometimes called released) channel materials 104 form the corresponding nanoribbons 104, and the suspended channel materials 108 form the corresponding nanoribbons 108.

Referring again to FIG. 5, the method 500 proceeds from 532 to 536, where the final gate structure is formed, as illustrated in FIGS. 6K and 6K1. The structures of FIGS. 6K and 6K1 are respectively formed from the corresponding structures of FIGS. 6J and 6J1. The gate electrode 114 of the gate structure is illustrated in FIGS. 6K and 6K1. The final gate structure also comprises gat dielectric 120 illustrated in FIGS. 1A and 2A. The final gate structure is formed using appropriate techniques for forming such final gate structures in stacked GAA devices. The resultant structure of FIGS. 6K and 6K1 are respectively similar to the structures 100 and 200 of FIGS. 1A and 2A.

Referring again to FIG. 5, the method 500 proceeds from 536 to 540, where a general integrated circuit (IC) is completed, as desired, in accordance with some embodiments. Such additional processing to complete an IC may include forming source, drain, and/or gate contacts, back-end or back-end-of-line (BEOL) processing to form one or more frontside and/or backside metallization layers (e.g., such as a frontside logic interconnect structure and/or a backside power delivery network structure). Any other suitable processing may be performed, as will be apparent in light of this disclosure.

Note that the processes in method 500 are shown in a particular order for ease of description. However, one or more of the processes may be performed in a different order or may not be performed at all (and thus be optional), in accordance with some embodiments. Numerous variations on method 500 and the techniques described herein will be apparent in light of this disclosure.

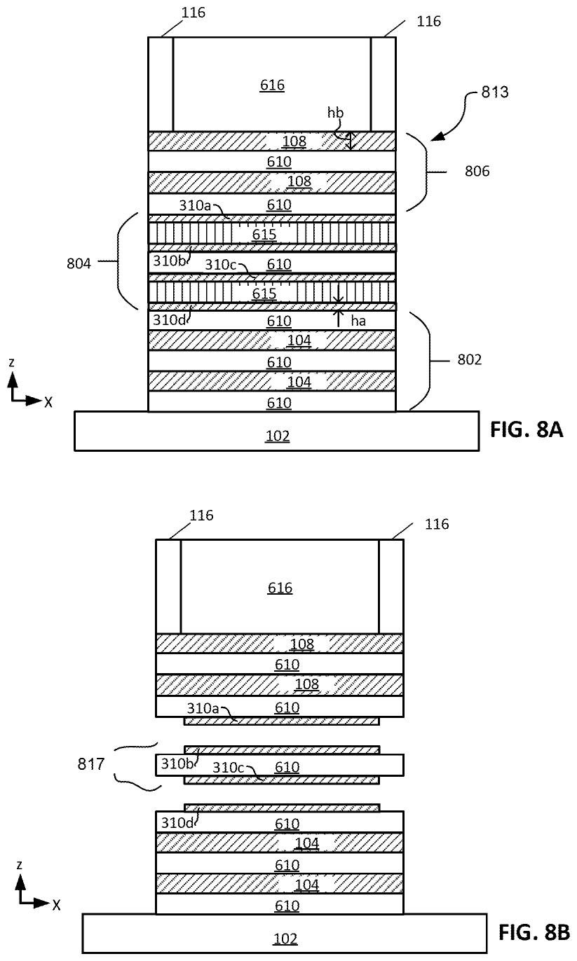

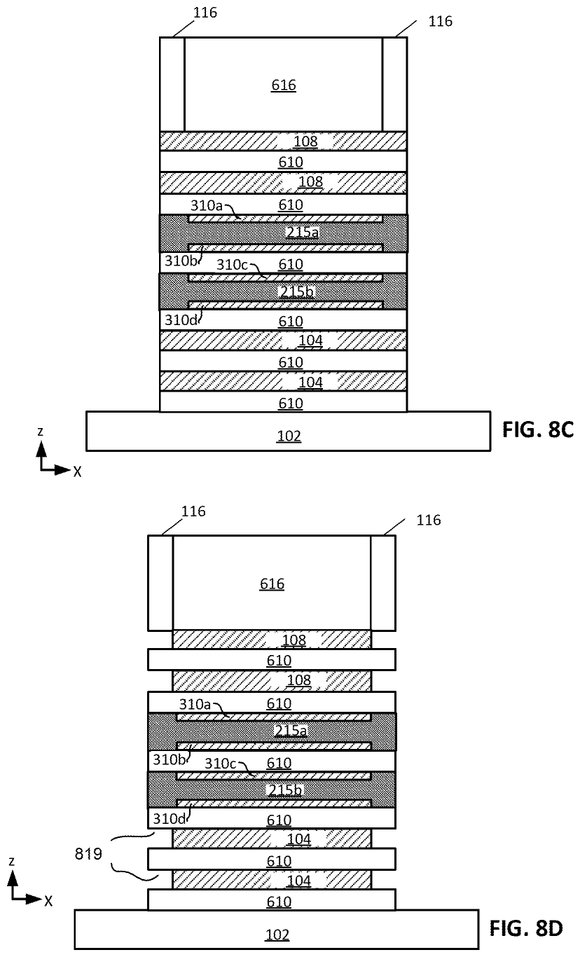

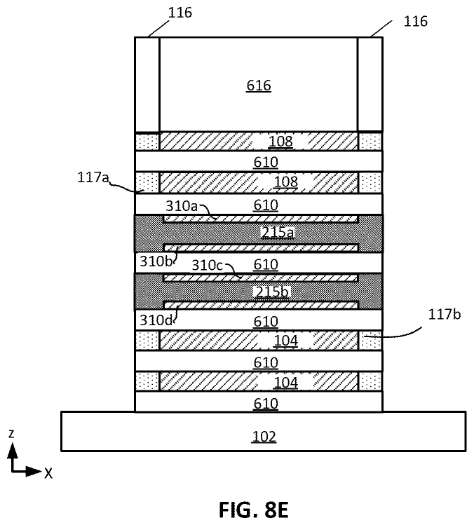

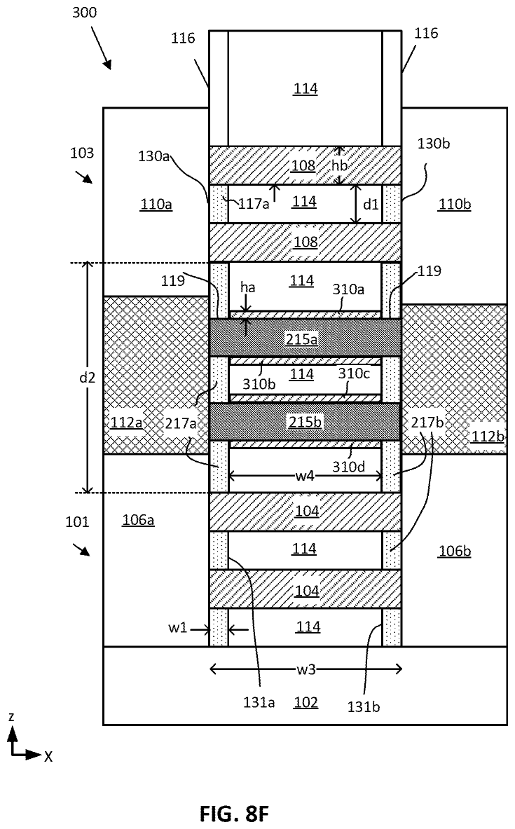

FIG. 7 illustrates a flowchart depicting a method 700 of forming any of the example integrated circuit structure 300 of FIG. 3, in accordance with an embodiment of the present disclosure. FIGS. 8A, 8B, 8C, 8D, 8E, and 8F collectively illustrate cross-sectional views of an example integrated circuit device semiconductor structure (e.g., the integrated circuit structure 300 of FIG. 3) in various stages of processing, in accordance with an embodiment of the present disclosure.

Referring to method 700 of FIG. 7, at 708, a stack of layers is formed, where the stack comprises (i) a lower portion 802 that includes alternating layers of channel material 104 and first sacrificial material 610, (ii) an intermediate portion 804 that includes alternating layers of partial nanoribbons 310, second sacrificial material 615, and the first sacrificial material 610, and (iii) an upper portion 806 that includes alternating layers of channel material 108 and the first sacrificial material 610. The stack of layers is recessed, to form one or more multilayer fins, e.g., as also discussed with respect to similar process 504 of method 500. Process 508 also includes forming dummy gate structure over the fin, e.g., as also discussed with respect to similar process 508 of method 500. Furthermore, source and drain trenches are formed adjacent to the dummy gate structure and the fin 613, as also discussed with respect to method 500. The resultant structure is illustrated in FIG. 8A.

In FIG. 8A, the layers 310 comprising the semiconductor materials (e.g., similar to the channel materials 104 and/or 108) are referred to as “partial” nanoribbons (see FIG. 3), but the layers 310 are not yet “partial”. For example, in FIG. 8A, a length of the layers 310 is substantially similar to a length of the layers of channel materials 104, 108. However, as illustrated and as also discussed with respect to FIG. 3 herein above, a height ha (see FIG. 8A, also see FIG. 3) of the layers 310 is less than a height hb of the layers of channel materials 104, 108, and the eventual partial nanoribbons 310 will be thinner than the nanoribbons 104, 108.

Referring again to FIG. 7, the method 700 proceeds from 708 to 712, where the sacrificial material 615 are removed (e.g., etched) to form corresponding recesses 817, and also, end portions of the partial nanoribbons 310 are also recessed. Removal process of the sacrificial material 615 has also been discussed herein above with respect to FIG. 6D1. In an example, the etch process to remove the sacrificial material 615 does not substantially etch the sacrificial material 610 and the channel materials of the layers 104, 108, and 310. However, because of the smaller height ha of the partial nanoribbons 310, end portions of the partial nanoribbons 310 are recessed. Such recessing is substantially avoided for the layers of channel materials 104, 108, e.g., due to their substantially greater height hb, in an example.

Referring again to FIG. 7, the method 700 proceeds from 712 to 716, where sections 215a, 215b of the gate spacer structures are formed within the recesses 817, e.g., as illustrated in FIG. 8C. Process 716 of method 700 has been discussed in detail with respect to similar process 516 of method 500.

Referring again to FIG. 7, the method 700 proceeds from 716 to 720, where end portions of the layers of the sacrificial material 610 are removed to form recesses 819, e.g., as illustrated in FIG. 8D. Process 720 of method 700 has been discussed in detail with respect to similar process 520 of method 500.

Referring again to FIG. 7, the method 700 proceeds from 720 to 724, where sections 117a, 117b of the gate spacer structures are formed within the recesses 819, e.g., as illustrated in FIG. 8E. Process 724 of method 700 has been discussed in detail with respect to similar process 524 of method 500.

Referring again to FIG. 7, the method 700 proceeds from 724 to 728, where source and drain regions of the upper and lower devices 103, 101 are formed, followed by removal of the dummy gate structure and releasing the nanoribbons 104, 108 (e.g., by removing the layers of sacrificial materials 610), and the final gate structure is formed, as illustrated in FIG. 8F. Process 728 of method 700 has been discussed in detail with respect to similar processes 528, 532, and 536 of method 500. The resultant structure of FIG. 8F is same as the structure 300 of FIG. 3.

Referring again to FIG. 7, the method 700 proceeds from 728 to 732, where a general integrated circuit (IC) is completed, as desired, in accordance with some embodiments. Such additional processing to complete an IC may include forming source, drain, and/or gate contacts, back-end or back-end-of-line (BEOL) processing to form one or more frontside and/or backside metallization layers (e.g., such as a frontside logic interconnect structure and/or a backside power delivery network structure). Any other suitable processing may be performed, as will be apparent in light of this disclosure.

Note that the processes in method 700 are shown in a particular order for ease of description. However, one or more of the processes may be performed in a different order or may not be performed at all (and thus be optional), in accordance with some embodiments. Numerous variations on method 700 and the techniques described herein will be apparent in light of this disclosure.

FIG. 9 illustrates a flowchart depicting a method 900 of forming any of the example integrated circuit structure 400 of FIG. 4A, in accordance with an embodiment of the present disclosure. FIGS. 10A, 10B, 10C, 10D, 10E, and 10F collectively illustrate cross-sectional views of an example integrated circuit device semiconductor structure (e.g., the integrated circuit structure 400 of FIG. 4A) in various stages of processing, in accordance with an embodiment of the present disclosure.

Referring to method 900 of FIG. 9, at 908, a stack of layers is formed, where the stack comprises (i) a lower portion 1002 that includes alternating layers of channel material 104 and first sacrificial material 610, (ii) an intermediate portion 1004 that includes a layer of second sacrificial material 615 between two layers of sacrificial nanoribbons 1010a and 1010b, and (iii) an upper portion 1006 that includes alternating layers of channel material 108 and the first sacrificial material 610, and where the stack of layers is recessed to form a fin 1013, e.g., as also discussed with respect to process 504 of method 500. Furthermore, a dummy gate structure is formed over the fin 1013, and source and drain trenches are formed adjacent to the dummy gate structure and the fin 1013, as also discussed with respect to process 508 of method 500.

In an example, the sacrificial nanoribbons 1010a comprises semiconductor material (e.g., same as the channel materials 104 and/or 108), e.g., similar to the partial nanoribbons 310 of FIG. 8A. In an example, a thickness of each of the sacrificial nanoribbons 1010a, 1010b is about hs, as illustrated in FIG. 10A, where the thickness hs is substantially less than a thickness of the layers of channel materials 104, 108 (e.g., similar to the thickness ha of FIG. 8A being less than a thickness hb of the nanoribbons 104, 108). Process 1008 also includes forming dummy gate structure above the stack, and removing exposed sections of the stack not under the dummy gate structure, to form a fin 1013, e.g., as also discussed with respect to process 508 of method 500. The resultant structure is illustrated in FIG. 10A.

Referring again to FIG. 9, the method 900 proceeds from 908 to 912, where the sacrificial material 615 is removed completely, end portions of the sacrificial material 610 are removed, and end portions of the sacrificial nanoribbons 1010 also removed, which may also result in thinning of the sacrificial nanoribbons 1010. The resultant structure comprising recesses 1017 (e.g., formed by the above discussed removals) is illustrated in FIG. 10B. In an example, the sacrificial material 615 etches faster than the sacrificial material 610, and hence, the sacrificial material 615 is removed completely, while only partial end portions of the sacrificial material 610 are removed. In another example, a series of etch processes are employed in the process 912, e.g., to separately remove the sacrificial materials 610 and 615. In an example, the etch process of 912 does not substantially etch the channel materials of the layers 104, 108, e.g., due to the relatively greater thickness of the layers 104, 108. However, because of the smaller height hs (see FIG. 10A) of the sacrificial nanoribbons 1010, end portions of the sacrificial nanoribbons 1010 are recess and the sacrificial nanoribbons 1010 are thinned to a reduced height of hs' (where hs' is smaller than hs). Such recessing and/or thinning are substantially avoided for the layers of channel materials 104, 108, e.g., due to their substantially greater height.

Referring again to FIG. 9, the method 900 proceeds from 912 to 916, the gate spacer structure 418 is formed within the recesses 1017, e.g., as illustrated in FIG. 10C. Formation of gate spacer structure has been discussed herein earlier, e.g., with respect to process 516 of method 500. Note that the entire gate spacer structure 418 is deposited in a single deposition process, and hence, no seam, grain boundary, or other interfaces are not formed within various sections of the gate spacer structure 418.

Referring again to FIG. 9, the method 900 proceeds from 916 to 920, where source and drain regions of the upper and lower devices 103, 101 are formed, e.g., as illustrated in FIG. 10D. Process of forming the source and drain regions (and intervening isolation structures 112) have been discussed herein previously with respect to method 500.

Referring again to FIG. 9, the method 900 proceeds from 920 to 924, where the dummy gate structure is removed and the nanoribbons 104, 108 are released (e.g., by removing the layers of sacrificial materials 610), e.g., as illustrated in FIG. 10E. Process of removing the dummy gate and releasing the nanoribbon have been discussed herein previously with respect to method 500.

Note that during the process 924 (e.g., an etch process) to remove the layers of sacrificial materials 610, the nanoribbons 104, 108 are not substantially etched, e.g., owing to a relatively high thickness of the nanoribbons. However, in an example, the relatively thinner (e.g., height of hs′, see FIG. 10B) sacrificial nanoribbons 1010a, 1010b may be completely removed, e.g., as illustrated in FIG. 10E, which would eventually result in forming the structure 400 of FIG. 4A. However, in another example, remnants of the sacrificial nanoribbons 1010a, 1010b may remain on the horizontal section of the gate spacer structure 418, as discussed with respect to the structure 400b of FIG. 4B.

Referring again to FIG. 9, the method 900 proceeds from 924 to 928, where the final gate structure is formed, as illustrated in FIG. 10F. Process 928 of method 900 has been discussed in detail with respect to similar processes 536 of method 500. The resultant structure of FIG. 10F is same as the structure 400 of FIG. 4A.

Referring again to FIG. 9, the method 900 proceeds from 928 to 932, where a general integrated circuit (IC) is completed, as desired, in accordance with some embodiments. Such additional processing to complete an IC may include forming source, drain, and/or gate contacts, back-end or back-end-of-line (BEOL) processing to form one or more frontside and/or backside metallization layers (e.g., such as a frontside logic interconnect structure and/or a backside power delivery network structure). Any other suitable processing may be performed, as will be apparent in light of this disclosure.

Note that the processes in method 900 are shown in a particular order for ease of description. However, one or more of the processes may be performed in a different order or may not be performed at all (and thus be optional), in accordance with some embodiments. Numerous variations on method 900 and the techniques described herein will be apparent in light of this disclosure.

Example System

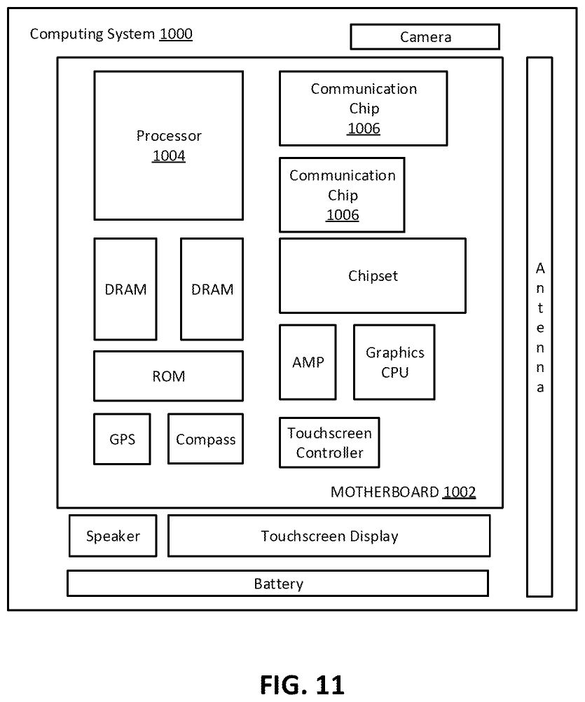

FIG. 11 illustrates a computing system 1000 implemented with integrated circuit structures formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following examples pertain to further embodiments, from which numerous permutations and configurations will be apparent.

Example 1. An integrated circuit comprising: an upper body extending in a first direction from an upper source region to an upper drain region, and a lower body extending in the first direction from a lower source region to a lower drain region, the upper body spaced vertically from the lower body in a second direction orthogonal to the first direction, each of the upper body and the lower body comprising semiconductor material; and a gate spacer structure adjacent to the upper source region and the lower source region, the gate spacer structure comprising (i) a first section having a first dimension in the first direction, and (ii) a second section having a second dimension in the first direction, wherein the first dimension is different from the second dimension by at least 1 nanometer (nm).

Example 2. The integrated circuit of example 1, wherein each of the first section and the second comprises dielectric material, and wherein there is an interface between the dielectric material of the first section and the dielectric material of the second section.

Example 3. The integrated circuit of any one of examples 1-2, wherein the dielectric material of the first section and the dielectric material of the second section are elementally same.

Example 4. The integrated circuit of any one of examples 1-2, wherein the first section comprises a first dielectric material, and the second section comprises a second dielectric material that is compositionally different from the first dielectric material.

Example 5. The integrated circuit of any one of examples 1-4, wherein: the first section extends in the second direction, the first section (i) separating the upper source region from an upper gate stack and (ii) separating the lower source region from a lower gate stack; and the second section extends in the first direction.

Example 6. The integrated circuit of example 5, wherein the gate spacer structure is a first gate spacer structure, and wherein the integrated circuit further comprises: a second gate spacer structure comprising a third section that extends in the second direction, and separates the upper and lower drain regions from the upper and lower gate stacks, respectively.

Example 7. The integrated circuit of example 6, wherein the second section extends from the first section towards the third section.

Example 8. The integrated circuit of any one of examples 6-7, wherein the second section extends in the first direction from the first section to the third section.

Example 9. The integrated circuit of any one of examples 6-8, wherein the second gate spacer structure further comprises a fourth section that extends in the first direction, from the third section and towards the first section, and wherein the fourth section has a third dimension in the first direction that is different from the first dimension by at least 1 nm.

Example 10. The integrated circuit of example 9, wherein the second section and the fourth section conjoins and form a horizontal section extending laterally from the first section to the third section, such that the first and second gate spacer structures combine to form a continuous gate spacer structure.

Example 11. The integrated circuit of any one of examples 9-10, wherein each of the first, second, third, and fourth sections comprise dielectric material, and wherein the second section and the fourth section of the gate spacer structure are laterally separated by conductive material.

Example 12. The integrated circuit of any one of examples 9-10, wherein the second section and the fourth section of the gate spacer structure are laterally separated by an isolation region comprising dielectric material, wherein the isolation region is between (i) the upper gate stack that is laterally between the upper source region and the upper drain region and (ii) the lower gate stack that is laterally between the lower source region and the lower drain region.

Example 13. The integrated circuit of any one of examples 1-12, further comprising: an additional body comprising the semiconductor material that is in contact with the second section, the additional body extending in the first direction, wherein the additional body is not in contact with any of the upper source region, the lower source region, the upper drain region, or the lower drain region.

Example 14. The integrated circuit of example 13, further comprising: a first isolation structure comprising dielectric material between the upper source region and the lower source region; and a second isolation structure comprising dielectric material between the upper drain region and the lower drain region; wherein the additional body extends laterally between the first isolation structure and the second isolation structure.

Example 15. The integrated circuit of example 14, wherein the second section extends laterally between the first isolation structure and the second isolation structure.

Example 16. The integrated circuit of any one of examples 13-15, wherein a height of the additional body is at least 2 nm less than a height of one or both the upper and lower bodies, the heights measured in the second direction.

Example 17. The integrated circuit of any one of examples 1-16, wherein an end portion of the second section is wrapped around by the first section.

Example 18. The integrated circuit of any one of examples 1-17, wherein: the gate spacer structure has (i) a first sidewall facing the upper and lower source regions and (ii) a second sidewall opposite the first sidewall; a first portion of the first sidewall is within the first section, a second portion of the first sidewall is within the second section, and the first and second portions of the first sidewall are coplanar; a third portion of the second sidewall is within the first section, a fourth portion of the second sidewall is within the second section, and the third and fourth portions of the second sidewall are laterally offset from one another by at least 1 nm, thereby resulting in the first dimension being different from the second dimension by at least 1 nm.

Example 19. The integrated circuit of any one of examples 1-18, wherein the gate spacer structure further comprises a third section substantially parallel to the second section, the third section has a third dimension in the first direction that is within 1 nm of the second dimension in the first direction, wherein the first section wraps around an end portion of each of the second section and the third section.

Example 20. An integrated circuit structure comprising: an upper device comprising an upper source region, an upper drain region, an upper body of semiconductor material laterally extending from the upper source region to the upper drain region, and an upper gate structure wrapping around at least a corresponding section of the upper body; a lower device comprising a lower source region, a lower drain region, a lower body of semiconductor material laterally extending from the lower source region to the lower drain region, and a lower gate structure wrapping around at least a corresponding section of the lower body; and a gate spacer structure including (i) an upper portion separating the upper gate structure from the upper source region, (ii) a lower portion separating the lower gate structure from the lower source region, and (iii) an intermediate portion between the upper and lower portions, the intermediate portion extending laterally within at least one of the upper and lower gate structures, or extending between the upper and lower gate structures.

Example 21. The integrated circuit structure of example 20, wherein the upper gate structure comprises an upper gate electrode, the lower gate structure comprises a lower gate electrode, a section of the upper gate electrode is above a section of the intermediate portion, and a section of the lower gate electrode is below a section of the intermediate portion.

Example 22. The integrated circuit structure of example 21, wherein the upper gate electrode and the lower gate electrode form a continuous and monolithic gate electrode structure.

Example 23. The integrated circuit structure of any one of examples 20-21, wherein the upper gate structure and the lower gate structure are separated by an isolation region, and the intermediate portion extends within the isolation region.

Example 24. The integrated circuit structure of any one of examples 20-23, further comprising: a first isolation structure between the upper source region and the lower source region; and a second isolation structure between the upper drain region and the lower drain region, wherein the intermediate portion is laterally between the first isolation structure and the second isolation structure.

Example 25. The integrated circuit structure of example 24, wherein the intermediate portion extends from the first isolation structure to the second isolation structure.

Example 26. The integrated circuit structure of any one of examples 20-25, further comprising: an intermediate body comprising semiconductor material in contact with the intermediate portion, wherein the intermediate body is not in contact with any of the upper source region, the lower source region, the upper drain region, or the lower drain region.

Example 27. The integrated circuit structure of any one of examples 20-26, wherein each of the upper portion and the intermediate portion comprises dielectric material, and are compositionally different, with an interface between the upper portion and the intermediate portion.

Example 28. The integrated circuit structure of any one of examples 20-27, wherein each of the lower portion and the intermediate portion comprises dielectric material, and are compositionally different, with an interface between the lower portion and the intermediate portion.

Example 29. An integrated circuit structure comprising: an upper source region, a lower source region below the upper source region, and an isolation region between the upper source region and the lower source region; and a spacer structure comprising dielectric material and having (i) an outer sidewall adjacent to the upper source region, the lower source region, and the isolation region, and (ii) an inner sidewall opposite the outer sidewall, wherein an entirety of the outer sidewall that is adjacent to the upper source region, the lower source region, and the isolation region is substantially coplanar, and wherein the inner sidewall has (i) a first section and (ii) a second section that is laterally offset from the first section by at least 1 nanometer (nm).

Example 30. The integrated circuit structure of example 29, wherein the second section of the inner sidewall is laterally offset from the first section of the inner sidewall by at least 5 nm.

Example 31. The integrated circuit structure of any one of examples 29-30, further comprising: an upper body comprising first semiconductor material and extending laterally from the upper source region, wherein an end portion of the upper body is in contact with the upper source region; a lower body comprising second semiconductor material and extending laterally from the lower source region, wherein an end portion of the lower body is in contact with the lower source region; and an intermediate body comprising third semiconductor material and extending laterally, wherein the upper body is above the intermediate body and the lower body is below the intermediate body, and wherein an end portion of the intermediate body is not in contact with any source or drain regions.

Example 32. The integrated circuit structure of example 31, wherein the spacer structure wraps around the end portions of each of the upper body and the lower body, and the spacer structure does not wrap around the end portion of the intermediate body.

The foregoing description of the embodiments of the disclosure has been presented for the purposes of illustration and description. It is not intended to be exhaustive or to limit the disclosure to the precise forms disclosed. Many modifications and variations will be apparent in light of this disclosure. It is intended that the scope of the disclosure be limited not by this detailed description, but rather by the claims appended hereto.

What is claimed is:

1. An integrated circuit comprising:
an upper body extending in a first direction from an upper source region to an upper drain region, and a lower body extending in the first direction from a lower source region to a lower drain region, the upper body spaced vertically from the lower body in a second direction orthogonal to the first direction, each of the upper body and the lower body comprising semiconductor material; and
a gate spacer structure adjacent to the upper source region and the lower source region, the gate spacer structure comprising (i) a first section having a first dimension in the first direction, and (ii) a second section having a second dimension in the first direction, wherein the first dimension is different from the second dimension by at least 1 nanometer (nm).

2. The integrated circuit of claim 1, wherein each of the first section and the second comprises dielectric material, and wherein there is an interface between the dielectric material of the first section and the dielectric material of the second section.

3. The integrated circuit of claim 1, wherein the dielectric material of the first section and the dielectric material of the second section are elementally same.

4. The integrated circuit of claim 1, wherein the first section comprises a first dielectric material, and the second section comprises a second dielectric material that is compositionally different from the first dielectric material.

5. The integrated circuit of claim 1, wherein:
the first section extends in the second direction, the first section (i) separating the upper source region from an upper gate stack and (ii) separating the lower source region from a lower gate stack; and
the second section extends in the first direction.

6. The integrated circuit of claim 5, wherein the gate spacer structure is a first gate spacer structure, and wherein the integrated circuit further comprises:
a second gate spacer structure comprising a third section that extends in the second direction, and separates the upper and lower drain regions from the upper and lower gate stacks, respectively.

7. The integrated circuit of claim 6, wherein the second section extends in the first direction from the first section to the third section.

8. The integrated circuit of claim 6, wherein the second gate spacer structure further comprises a fourth section that extends in the first direction, from the third section and towards the first section, and wherein the fourth section has a third dimension in the first direction that is different from the first dimension by at least 1 nm.

9. The integrated circuit of claim 8, wherein the second section and the fourth section conjoins and form a horizontal section extending laterally from the first section to the third section, such that the first and second gate spacer structures combine to form a continuous gate spacer structure.

10. The integrated circuit of claim 9, wherein each of the first, second, third, and fourth sections comprise dielectric material, and wherein the second section and the fourth section of the gate spacer structure are laterally separated by conductive material.

11. The integrated circuit of claim 8, wherein the second section and the fourth section of the gate spacer structure are laterally separated by an isolation region comprising dielectric material, wherein the isolation region is between (i) the upper gate stack that is laterally between the upper source region and the upper drain region and (ii) the lower gate stack that is laterally between the lower source region and the lower drain region.

12. The integrated circuit of claim 1, further comprising:
an additional body comprising the semiconductor material that is in contact with the second section, the additional body extending in the first direction, wherein the additional body is not in contact with any of the upper source region, the lower source region, the upper drain region, or the lower drain region.

13. The integrated circuit of claim 12, further comprising:
a first isolation structure comprising dielectric material between the upper source region and the lower source region; and
a second isolation structure comprising dielectric material between the upper drain region and the lower drain region;
wherein the additional body extends laterally between the first isolation structure and the second isolation structure.

14. The integrated circuit of claim 13, wherein the second section extends laterally between the first isolation structure and the second isolation structure.

15. The integrated circuit of claim 12, wherein a height of the additional body is at least 2 nm less than a height of one or both the upper and lower bodies, the heights measured in the second direction.

16. The integrated circuit of claim 1, wherein:
the gate spacer structure has (i) a first sidewall facing the upper and lower source regions and (ii) a second sidewall opposite the first sidewall;
a first portion of the first sidewall is within the first section, a second portion of the first sidewall is within the second section, and the first and second portions of the first sidewall are coplanar;
a third portion of the second sidewall is within the first section, a fourth portion of the second sidewall is within the second section, and the third and fourth portions of the second sidewall are laterally offset from one another by at least 1 nm, thereby resulting in the first dimension being different from the second dimension by at least 1 nm.

17. An integrated circuit structure comprising:
an upper device comprising an upper source region, an upper drain region, an upper body of semiconductor material laterally extending from the upper source region to the upper drain region, and an upper gate structure wrapping around at least a corresponding section of the upper body;
a lower device comprising a lower source region, a lower drain region, a lower body of semiconductor material laterally extending from the lower source region to the lower drain region, and a lower gate structure wrapping around at least a corresponding section of the lower body; and
a gate spacer structure including (i) an upper portion separating the upper gate structure from the upper source region, (ii) a lower portion separating the lower gate structure from the lower source region, and (iii) an intermediate portion between the upper and lower portions, the intermediate portion extending laterally within at least one of the upper and lower gate structures, or extending between the upper and lower gate structures.

18. The integrated circuit structure of claim 17, wherein the upper gate structure comprises an upper gate electrode, the lower gate structure comprises a lower gate electrode, a section of the upper gate electrode is above a section of the intermediate portion, and a section of the lower gate electrode is below a section of the intermediate portion.

19. The integrated circuit structure of claim 17, wherein the upper gate structure and the lower gate structure are separated by an isolation region, and the intermediate portion extends within the isolation region.

20. The integrated circuit structure of claim 17, further comprising:
a first isolation structure between the upper source region and the lower source region; and
a second isolation structure between the upper drain region and the lower drain region,
wherein the intermediate portion is laterally between the first isolation structure and the second isolation structure.

21. The integrated circuit structure of claim 17, further comprising:
an intermediate body comprising semiconductor material in contact with the intermediate portion,
wherein the intermediate body is not in contact with any of the upper source region, the lower source region, the upper drain region, or the lower drain region.

22. An integrated circuit structure comprising:
an upper source region, a lower source region below the upper source region, and an isolation region between the upper source region and the lower source region; and
a spacer structure comprising dielectric material and having (i) an outer sidewall adjacent to the upper source region, the lower source region, and the isolation region, and (ii) an inner sidewall opposite the outer sidewall,
wherein an entirety of the outer sidewall that is adjacent to the upper source region, the lower source region, and the isolation region is substantially coplanar, and
wherein the inner sidewall has (i) a first section and (ii) a second section that is laterally offset from the first section by at least 1 nanometer (nm).

23. The integrated circuit structure of claim 22, wherein the second section of the inner sidewall is laterally offset from the first section of the inner sidewall by at least 5 nm.

24. The integrated circuit structure of claim 22, further comprising:
an upper body comprising first semiconductor material and extending laterally from the upper source region, wherein an end portion of the upper body is in contact with the upper source region;
a lower body comprising second semiconductor material and extending laterally from the lower source region, wherein an end portion of the lower body is in contact with the lower source region; and
an intermediate body comprising third semiconductor material and extending laterally, wherein the upper body is above the intermediate body and the lower body is below the intermediate body, and wherein an end portion of the intermediate body is not in contact with any source or drain regions.
